(19) United States
(12) Patent Application Publication
(10) Pub. No.: US 2008/0191153 A1
(43) Pub. Date: Aug. 14, 2008

(54) System For Delivery Of Reagents From Solid Sources Thereof

(75) Inventors: Paul J. Marganski, Seymour, CT (US); James Dietz, Allison Park, PA (US); Joseph D. Sweeney, Winsted, CT (US)

Correspondence Address: INTELLECTUAL PROPERTY / TECHNOLOGY LAW, PO BOX 14329, RESEARCH TRIANGLE PARK, NC, 27709, US

(73) Assignee: ADVANCED TECHNOLOGY MATERIALS, INC., Danbury, CT (US)

(21) Appl. No.: 11/908,964

(22) PCT Filed: Mar. 9, 2006
(86) PCT No.: PCT/US06/08530

§ 371 Date: Feb. 11, 2008

Related U.S. Application Data
(60) Provisional application No. 60/662,515, filed on Mar. 16, 2005.
(60) Provisional application No. 60/662,396, filed on Mar. 16, 2005.

(51) Int. Cl. H01J 37/08; H01L 21/306; B08B 3/08; C23C 16/448; B08B 13/00; B08B 9/00

(52) U.S. Cl. 250/492.21; 156/345.18; 134/201; 118/715; 134/107; 134/22.1

(57) ABSTRACT

A system (10) for delivery of reagent from a solid source thereof, comprising a structure (16, 22, 24) arranged to retain a solid source material (30) in confinement by at least a portion of the structure, for heating and generation of vapor from the solid source material by volatilization thereof, a heat source (82) arranged to heat the solid source material for such volatilization, and a vapor dispensing assembly (52, 54) arranged to discharge the vapor from the system. A high conductance valve (1510) is also described, suitable for use as a dispensing control valve for a reagent storage and dispensing vessel, e.g., a vessel containing a semiconductor manufacturing reagent that is dispensed at low pressure. The high conductance valve includes a valve body (1512) in which inlet and outlet passages are substantially perpendicular to one another, with their interior extremities communicating with a valve chamber (1536) containing a selectively positionable valve element movable between a fully open and fully closed position. Valve flow coefficient (C_{V}) values on the order of 2.7 to 2.9 are achievable by such high conductance valve, enabling the valve to achieve superior dispensing operation even in extremely low pressure regimes, e.g., below 20 torr.

### CROSS-REFERENCE TO RELATED APPLICATIONS

The benefit of priority of the following U.S. Provisional Patent Applications is hereby claimed: U.S. Provisional Patent Application No. 60/662,515 filed Mar. 16, 2005 in the names of Paul J. Marganski, James I. Dietz and Joseph D. Sweeney for “SYSTEM FOR DELIVERY OF REAGENTS FROM SOLID SOURCES THEREOF” and U.S. Provisional Patent Application No. 60/662,396 filed Mar. 16, 2005 in the names of PAUL J. MARGANSKI and JOSEPH D. SWEENEY for “HIGH CONDUCTANCE VALVE FOR USE IN DELIVERY OF LOW PRESSURE FLUIDS.”

### FIELD OF THE INVENTION

The present invention relates generally to packaging of source reagents and to material delivery systems. In specific aspects, the invention relates to delivery of reagents from solid sources thereof, to corresponding containers for storage and dispensing of source reagents, and to high conductance valves that are useful for the delivery of low pressure fluids, e.g., gases or vapors employed in the manufacture of semiconductor devices, and to systems and methods using such valves.

### DESCRIPTION OF THE RELATED ART

Chemical reagents are used in a wide variety of forms. In some instances, the chemical reagent is used in a vapor form, and is derived from a source that initially is in a solid form, e.g., at ambient temperature and pressure conditions. In such circumstance, the solid source may be volatilized to form the desired reagent vapor.

Examples of solid sources include borane compounds such as decaborane and octadecaborane, which are used as sources for boron doping in the manufacture of semiconductors.

In the use of solid source materials to provide vapor reagents, the solid material may be heated to induce phase transition to the vapor phase, e.g., by sublimation, or by effecting a serial solid-to-liquid-to-vapor transition.

Unfortunately, conventional approaches of heating solid sources for such vapor generation suffer from a number of deficiencies.

Typically, it is difficult to heat the solid source material in a manner that will ensure the desired temperature uniformity in the solid mass of source material. This problem is particularly acute in the case of sublimable solids, in which temperature non-uniformity can lead to sudden bursts of vapor being emitted from the solid. These bursts in turn create pressure perturbations in the reagent delivery system, and result in less-than-ideal vaporization and mass transport. For these reasons, improving temperature uniformity of the heated solid is a fundamental challenge in the use of solid source materials. Another adverse effect of temperature non-uniformity is the occurrence of condensation of vapors in unwanted locations of the process system, such as in transport lines and valves.

Another deficiency in the use of solid source materials is poor heat conduction in loosely packed solids. In many instances, the solid source material is initially provided in particulate, granular, powder or other discontinuous form. In such discontinuous form, the surface-to-volume ratio of the material may be extremely high, and the solid conduction of heat in the particle may be suitable to effect intraparticle heat transfer, but the interstitial voids between particles represent a limiting heat transfer resistance within the overall volume of particles. Accordingly, the bulk density of the solid material will affect conductive heat transport.

Another problem that is encountered in the use of solid source materials is level sensing of the source material in the supply vessel. Level sensing is desirable for process monitoring and control of the volatilization of the source material and delivery of vapor from the supply vessel. Since the supply vessel may be placed in a hot environment or equipped with heating components to facilitate heat conduction from the vessel walls to the solid source material contained in the vessel, the vessel may be constrained by available space or volume limitations that do not permit installation of a level sensing instrument package. Even if this is not the case, the level sensing instrument package may have associated temperature limitations that are incompatible with the temperatures encountered in heating of the vessel and solid material therein.

A further problem associated with the use of solid source materials is the problem of cleaning and reuse of the supply vessel. The volatilization of the solid in the vessel results in solids deposits on the interior walls of the vessel, which are desirably removed from the wall surfaces after the volatilization operation in completed. The removal of such solids for reuse of the vessel may be extremely time-consuming, labor-intensive and costly. Further, the cleaning process may itself introduce additional hazards such as toxicity, pyrophoricity, etc., associated with the cleaning agents that must be used.

For these reasons, the art continues to seek solutions that will facilitate the use of solid source materials in a manner that (i) minimizes the adverse effects of temperature inhomogeneity in the heated material and heat conduction resistance attributable to voids in the solid being heated, (ii) accommodates the monitoring of the level or amount of the solid material in the supply vessel as the volatilization operation is conducted, and (iii) facilitates the refurbishment and reuse of the supply vessel after the volatilization operation is completed.

As a related consideration in the delivery of low pressure gases and vapors, pressure drop across components of the fluid storage and delivery system, and along flow paths of the fluids, can be a significant issue.

For example, in the manufacture of semiconductor devices, it is common to use low pressure fluid reagents for applications such as ion implantation, chemical vapor deposition, etch and cleaning operations, etc.

Illustrative of low pressure fluid storage and delivery systems for such applications, U.S. Pat. No. 5,518,528 discloses a physical sorbent-based fluid storage and dispensing system in which the gas is stored and dispensed at low pressure, e.g., subatmospheric pressure levels below about 700 torr.

As another example, U.S. Pat. No. 6,089,027, U.S. Pat. No. 6,101,816 and U.S. Pat. No. 6,343,476 describe a fluid storage and dispensing system in which fluid is contained in a vessel having a fluid pressure regulator disposed in its interior volume and operative to discharge fluid through a dispensing assembly to flow circuitry coupled with a semiconductor tool. In such system, fluid can be dispensed for use at subatmospheric pressure levels by appropriate choice of the set point pressure of the fluid pressure regulator.

Due to the limited pressure driving force involved in these applications, flow of low pressure fluid reagents is constrained by system components that have excessive pressure drop characteristics. This circumstance entails potentially severe adverse effects on the downstream fluid-consuming process as well as on products made using the dispensed fluid.

Further, in the dispensing of fluid from vessels in which the fluid is stored on a physical adsorbent medium, the presence of excessive pressure drop in the components associated with a fluid supply vessel imposes a severe restriction on the ability to achieve high utilization of fluid from the vessel. The reason for this is that as the fluid is depleted, the pressure of the fluid declines to a final level at which no more fluid dispensing is possible. The remaining amount of fluid in the vessel then constitutes a “heels” or residuum that is unavailable for use.

For example, in a specific vessel of the type disclosed in the aforementioned U.S. Pat. No. 5,518,528, a gas such as arsine can be stored on the adsorbent. In subsequent use, such gas is desorbed and dispensed, down to a pressure of 10-20 torr, and thereafter the system is unable to dispense gas at a sufficiently high flow rate. If it were possible to reduce pressure drop in the system components used for dispensing, then dispensing could continue down to even lower pressure. If as a specific example, it were possible to achieve a continued dispensing operation down to a pressure of 2 torr, the resultant increase in fluid utilization from the vessel could be significant, e.g., on the order of about 10%.

For these reasons, the art continues to seek solutions that will facilitate delivery of low pressure fluids in applications such as those illustratively described above, in a manner that minimizes the adverse effect of pressure drop in fluid dispensing system components and flow circuitry.

### SUMMARY OF THE INVENTION

The present invention relates to systems for delivery of reagents from solid sources thereof, to packaging of source reagents, to material storage and dispensing systems including containers for storage and dispensing of source reagents, and to high conductance valves that are useful for the delivery of low pressure fluids, e.g., gases or vapors employed in the manufacture of semiconductor devices, and to systems and methods using such valves.

In one aspect, the invention relates to a system for delivery of reagent from a solid source thereof, comprising a structure arranged to retain a solid source material in confinement by at least a portion of the structure, for heating and generation of vapor from the solid source material by volatilization thereof, a heat source arranged to heat the solid source material for such volatilization, and a vapor dispensing assembly arranged to discharge the vapor from the system.

In another aspect, the invention relates to a method for delivery of reagent from a solid source thereof, comprising retaining a solid source material in confinement by at least a portion of a retention structure, heating the solid source material to generate vapor from the solid source material by volatilization thereof, and recovering such vapor.

The present invention in a further aspect relates to a valve having a valve flow coefficient of superior character, which is useful for the delivery of low pressure fluids, and to systems and methods for using such valves.

In one aspect, the invention relates to a high conductance valve including a valve body defining a valve chamber therein, an inlet passage communicating with the valve chamber and an outlet passage communicating with the valve chamber for respective ingress and egress of fluid into and out of the valve body, a valve element and actuator assembly permitting movement of the valve element between a fully open and fully closed position in the valve chamber, wherein the inlet passage and outlet passage together with the valve chamber permit fluid flow through the valve body when the valve element is in an opened position, and wherein the inlet and outlet passages are substantially perpendicular to one another.

Another aspect of the invention relates to a fluid delivery system including the valve of the invention, coupled to a fluid vessel.

A further aspect of the invention relates to a system for the manufacture of semiconductors comprising the valve of the invention coupled to a semiconductor manufacturing tool.

Yet another aspect of the invention relates to a method of using the valve of the invention, including disposing the valve in flow controlling relationship to a fluid, and selectively opening the valve to dispense the fluid to a fluid-consuming process, at a rate required by the process.

A still further aspect of the invention relates to a method of using the fluid delivery system of the invention, including providing a reagent in the vessel, and selectively opening the valve to dispense the reagent from the vessel to a reagent-consuming process, at a rate required by such process.

Other aspects, features and embodiments of the invention will be more fully apparent from the ensuing disclosure and appended claims.

### BRIEF DESCRIPTION OF THE DRAWINGS

FIG. 1 is a schematic front elevation view in partial cross-section of a system for delivery of reagent from solid source material, in accordance with one embodiment of the present invention.

FIG. 2 is a schematic front elevation view in partial cross-section of a system for delivery of reagent from solid source material, in accordance with another embodiment of the present invention.

FIG. 3 is a schematic representation of an arrangement for depositing vapor of a solid source material on a physical adsorbent medium in a storage and dispensing vessel.

FIG. 4 is a schematic representation of the storage and dispensing vessel of FIG. 3, in a subsequent dispensing mode, in which the adsorbed source material is desorbed and utilized in a downstream fluid-utilizing process system.

FIG. 5 is a perspective view of a source reagent article according to another embodiment of the invention, including a core body, on which is coated a solid source material.

FIG. 6 is a schematic representation of a delivery system utilizing a solid source material, according to yet another embodiment of the invention.

FIG. 7 is a reagent delivery system utilizing a solid source material, according to a further embodiment of the invention.

FIG. 8 is a reagent delivery system utilizing a solid source material, in an additional embodiment of the invention.

FIG. 9 is a perspective schematic view of an annular-shaped reagent dispensing vessel according to a further aspect of the invention, accommodating an interior positioning of a heating insert, as well as a heating jacket on exterior surface thereof.

FIG. 10 is an elevation view in partial section of a reagent delivery vessel according to one embodiment of the invention, featuring a series of horizontal trays in stacked arrangement, in which each tray is coated with or contains a solid source material.

FIG. 11 is a perspective view in partial section of a reagent delivery vessel according to a further aspect of the invention, incorporating an internal fluid collection manifold associated with porous tubes and/or porous rings.

FIG. 12 is a horizontally oriented reagent delivery vessel showing a solids volatilization technique according to a further aspect of the invention.

FIG. 13 is a schematic representation of a reagent delivery system according to another embodiment of the invention, featuring a buffer zone.

FIG. 14 is a perspective view of a reagent delivery vessel being inserted into a conformably shaped heating jacket, illustrating a further aspect of the invention in another embodiment.

FIG. 15 is a perspective view in partial section of a reagent delivery vessel according to a further aspect of the invention, featuring a collection manifold member coupled to a porous collection tube for discharge of volatilized solid vapor from the vessel, and showing associated monitoring and control componentry.

FIG. 16 is a schematic front elevation view, taken in cross-section, showing an elongate support member being coated with a solid source material, and the resultant coated article being translated through a heated zone to volatilize the solid source material to form vapor for a fluid-utilizing installation.

FIG. 17 is a schematic illustration of a mass of adsorbent and high thermal conductivity particles in admixture, and depicting some of the adsorbent and high thermal conductivity particles in cross-section, to show the coatings thereon of a surface film of solid source material, wherein the mass of particles is being impinged by energy mediating volatilization of the solid source material.

FIG. 18 is a schematic representation of a conveyor system for translating particles of solid source material through a heated zone to volatilize the solid source material and form a vapor for use in a vapor-utilization process.

FIG. 19 is a schematic representation of a fluidized bed system for generating vapor from solid source material coated on substrate particles, and for utilizing the resulting vapor in a downstream fluid-utilization facility.

FIG. 20 is a schematic representation of a vapor-generation system utilizing a solid source material, accessorized with various monitoring and control components.

FIG. 21 is an elevation view, in partial cross-section, of a solid source reagent delivery package, according to one embodiment of the invention.

FIG. 22 is an elevation view of a solid source reagent delivery package, as shrouded in a shrink-wrap film, as a security and tamper-resistant feature.

FIG. 23 is a graph of temperature, in ° C., and heat-flux sensor reading, in volts DC, as a function of elapsed time in minutes, at various locations of a source reagent supply package according to one embodiment of the invention.

FIG. 24 is an elevation view, in partial cross-section, of a solid source reagent delivery package, according to another embodiment of the invention.

FIG. 25 is a perspective view of a high conductance valve in accordance with one embodiment of the present invention.

FIG. 26 is a top plan view of the high conductance valve of FIG. 25.

FIG. 27 is a front elevation view of the high conductance valve of FIG. 25.

FIG. 28 is a sectional elevation view of the high conductance valve of FIG. 27, taken along line A-A thereof.

FIG. 29 is a schematic representation of a solid source reagent storage and dispensing vessel incorporating the high conductance valve of the invention, arranged in fluid flow communication with flow circuitry for delivery of fluid to a semiconductor manufacturing tool, with a heating jacket arranged for heating in response to the fluid needs of the semiconductor manufacturing tool.

### DETAILED DESCRIPTION OF THE INVENTION, AND PREFERRED EMBODIMENTS THEREOF

The present invention relates to a system and process for delivery of reagents from solid sources thereof.

In a particular aspect, the invention is usefully employed for volatilization of solid source materials for semiconductor manufacturing, including solid sources such as decaborane, octadecaborane, indium chloride, and the like, which are usefully submitted to sublimation in consequence of their low melting points and significant vapor pressures.

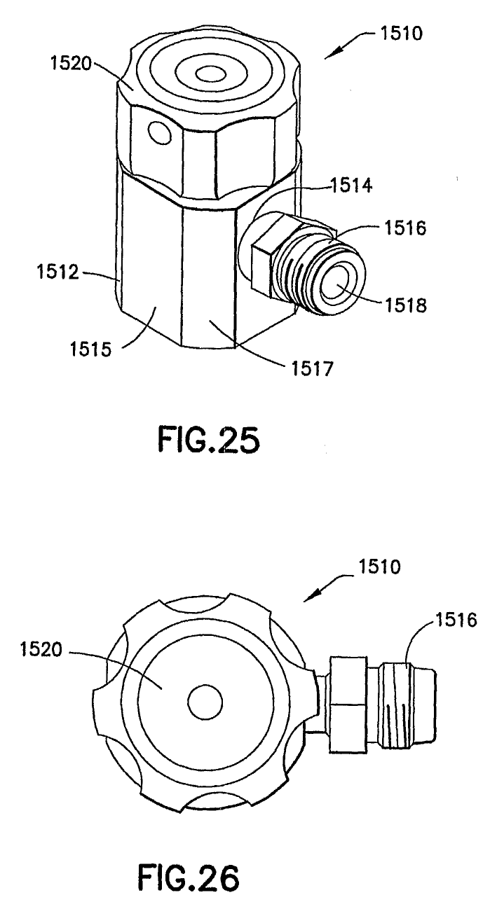

In many instances, the low pressure production of vapor from solid source materials will require high conductance flow circuitry and components, so that the delivery rate of the volatilized reagent satisfactorily matches the needs of the downstream processing system utilizing such volatilized reagent. In this respect, a particularly useful high conductance flow control valve is shown in FIGS. 25-29 hereof, as described more fully hereinafter.

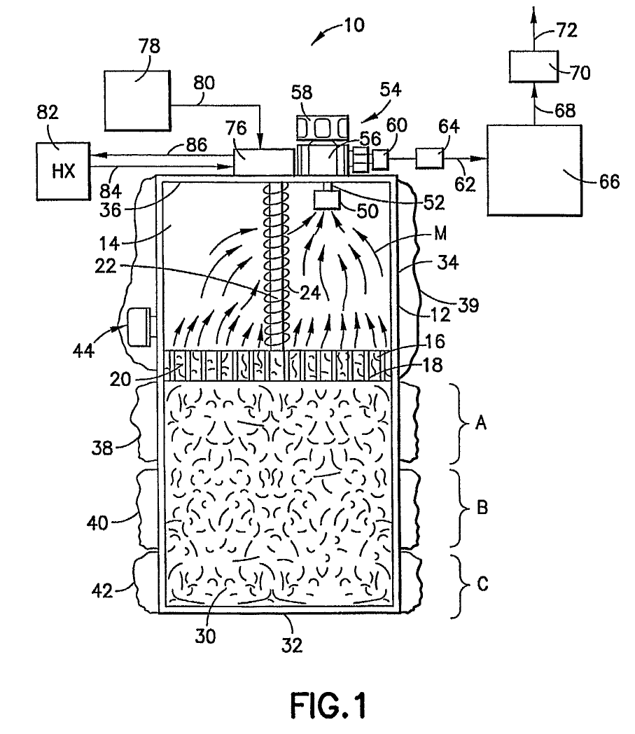

Referring now to the drawings, FIG. 1 is a schematic front elevation view in partial cross-section of a system 10 for delivery of reagent from solid source material, in accordance with one embodiment of the present invention.

The reagent delivery system 10 includes a vessel 12 having floor 32, sidewall 34 and top wall 36 defining an enclosed interior volume 14 in which is disposed a mass of a solid source material 30, at the lower portion of the vessel.

The vessel 12 in the interior volume 14 contains a porous plate member 16 having a series of channel openings 18 therein, extending from the bottom face of the plate member to the top surface thereof. The plate member 16 also is provided with interconnected porosity 20, which however is not in communication with the channel openings 18. The plate member 16 is joined at a center region thereof to the shaft 22, which in one embodiment is formed as a telescoping tubular assembly.

In one embodiment of the system shown in FIG. 1, the telescoping shaft 22 is circumscribed by a helically extending biasing spring 24. The shaft 22 and spring 24 are secured at their upper ends to the top wall 36 of the vessel 12, and are secured at their lower ends to the central region of the plate member 16. By this arrangement, the spring 24 exerts a compressive force on the top face of the plate member 16 and functions to urge the plate member downwardly, so that it maintains contact with the upper surface of the mass of solid source material 30, and bears compressively thereon.

The mass of solid source material may be in any suitable form, such as for example a granular, powder or other discontinuous form, to maximize surface to volume ratio of the material, as appropriately sized particles. In another embodiment, the mass of solid source material may be of a unitary monolithic block form, e.g., as formed by solidification of a liquid mass of the source material after heating of an initially solid volume of the material. While a monolithic block of the source material does not have high surface to volume ratio, it nonetheless is free of voids that may impede heat transfer throughout the bulk volume of a corresponding particulate mass of the solid source material. Heating of the solid source material may be effected by microwave heating or other impingement of heating energy on the solid source material.

The plate member 16 in one embodiment of the FIG. 1 system is heated, so that as it bears compressively against the top surface of the source material 30, the hot plate member causes the source material in contact with it to volatilize and the resultant vapor then flows through the channel openings 18 of the plate member and into the upper interior volume of the vessel.

The heating of the plate member 16 and the associated solid source material can be effected in any suitable manner. Heat transfer arrangements of varying types can be used to effect such heating, using various suitable heat transfer media, such as for example heat transfer fluids, which may be in gas or liquid form, as appropriate. In one embodiment of the invention, the shaft 22 is hollow and the hollow interior passage is in communication with a fluid reservoir and pump assembly 76 mounted on the top wall 36 of the vessel. The liquid in the reservoir and pump assembly 76 is heated by passage in line 86 from the reservoir of the assembly to the heat exchanger 82, in which the liquid is heated to appropriate temperature to effect volatilization of the solid source material, and the heated liquid is returned from the heat exchanger to the reservoir in the reservoir and pump assembly 76. The liquid then is pumped by a pump in the reservoir and pump assembly to the hollow passage in the interior of the shaft 22, from which the hot liquid flows into the interior porosity 20 of the plate member, circulating through the porosity and returning to the reservoir in assembly 76 by action of the pump therein. For such return flow of the heat transfer liquid to the reservoir, the interior of the shaft 22 will suitably contain a return flow passage of appropriate size to enable return under the pressure drop and driving force provided by the pump in the reservoir and pump assembly 76.

In this manner, a continuous flow of liquid through the plate member 16 is maintained, so that the temperature of the plate member is sufficient to volatilize the solid source material in proximity to the plate member, as the plate member is urged downwardly under the impetus of the biasing spring 24.

The volatilized solid source material then flows though the plate member channel openings, and flows upwardly, in the direction indicated by arrows M, to the filter 50 that is joined to the discharge tube 52 coupled through top wall 36 to the high conductance valve 54 positioned on the top surface of the top wall 36. The filter 50 is an optionally included feature of the solid source material vessel, and may be absent if not necessary to remove particulates or otherwise to provide a flow restriction in the vapor flow path. The high conductance valve 54 includes a valve body 56 to which is joined a discharge fitting 60. The valve includes a hand actuator 58 in the illustrated embodiment, but it will be realized that the valve 54 may be variously arranged with automatic actuator or other control apparatus, to selectively open the valve 54 for dispensing of vapor deriving from the solid source material in the vessel.

A particularly suitable high conductance valve useful in the broad practice of the present invention is shown in FIGS. 25-29 hereof, as described more fully hereinafter.

In the illustrated arrangement, as the solid source material sublimes and the mass 30 gets progressively smaller, the biasing action of the spring 24 maintains the plate member in contact with the source material. Level sensing of the solid source material may be effected in such arrangement by use of electrical contact(s), or magnetic, optical or other sensors, that provide an output indicative of the level of the plate member in contact with the upper surface of the bulk volume of solid source material, thereby producing an output reflecting the amount of solid source material that remains in the vessel for generation of source material vapor.

As another arrangement of the FIG. 1 system in which the plate member may be heated and the plate member urged downwardly as the source material is depleted to the vapor phase, the reservoir and pump assembly 76 may be coupled to a master reservoir 78 of hydraulic fluid that is heated and is pumped by the pump in the reservoir and pump assembly 76 into the hollow passage of the telescoping shaft 22. The heated hydraulic fluid then is flowed through the porosity 20 in the plate member 16, and concurrently, being pressurized, exerts hydraulic pressure on the plate member to force it downwardly as the telescoping shaft 22 is extended downwardly. In this manner, the contact of the heated plate member 16 with the top surface of the solid source material is maintained.

Various alternative or additional force mechanisms may be employed in specific embodiments of the invention to maintain the plate member 16 in contact with the top surface of the solid source material. For example, a transfer of momentum can be imparted to the plate member by a change in momentum of the heat transfer fluid in contacting and flowing away from the plate member. Additionally, a downwardly urging force is present by virtue of the weight of the plate member 16, and the weight of the plate member can therefore be selected to assist in maintaining a tight contact with the mass of solid source material in the vessel. Additional weight could be added to the plate member to increase the force maintaining the plate member in contact with the solid source material. Acceleration of the mass of the plate by imposition of an accelerating field (gravitational, electrical, etc.) is another force mechanism that may be employed.

It may also be advantageous in some applications of the embodiment shown in FIG. 1 to utilize the plate member 16 without any direct heating thereof, as simply a pressure-exerting member on the mass of the solid source material, and with heating being effected on the vessel. For example, if the plate member 16 and telescoping shaft 22 were to be made of a high conductivity material, e.g., aluminum, the conduction of heat from the vessel walls may be sufficient to carry heat to the plate member from which heat is transferred to the solid source material surface. The relative heating of the walls of the vessel and the heating of the plate member should be carried out to ensure that the temperature of the plate member is no higher than the vessel wall temperature, as necessary to avoid condensation of the vapor derived from the solid source material.

Generally, the vessel is externally heated, to ensure that vapors do not condense subsequent to their generation. For this purpose, the vessel may be provided with exteriorly circumscribing heating jackets 38, 40, and 42, along the portion of the vessel that is contacted by solid source material during the progressive vapor dispensing operation, as well as a vapor space heating jacket 39. This configuration of circumscribing heating jackets 38, 40, and 42 allows for level indication by monitoring of the pneumatic or hydraulic pressure inside the telescoping post in a shock-absorber type arrangement in which fluid is isolated in the post, and the pressure of the fluid decreases as the post lengthens as the source material is progressively depleted. It will be appreciated that the respective heating jackets are shown in a schematic fashion, without associated electrical wires and power supplies being illustrated, for ease of description.

The upper heating jacket 38 circumscribes the sidewall 34 of the vessel 12, to demarcate an upper heating zone denoted “A.” An intermediate heating jacket 40 circumscribes the sidewall 34 of the vessel beneath zone “A” and demarcates an intermediate heating zone “B.” A lower heating jacket 42 circumscribes the sidewall 34 of the vessel 12, to demarcate a lower heating zone “C.” The respective heating jackets may be coupled with suitable energizing components, e.g., power supplies, so that a respective one of the jackets is activated for heating of the associated zone of the solid source material, by conductive heat transfer through the sidewall into the solid source material.

In this fashion, the top heater 38 is activated when there is solid source material in zone “A,” intermediate heater 40 is activated when there is solid source material in zone “B” but not in zone “A,” and lower heater 42 is activated when there is solid source material in zone “C,” but not in either of zones “A” or “B.” The resultant heating of the solid source material in the corresponding zone causes the generated vapor from the solid to pass through the channel openings 18 in plate member 16, as described hereinabove, and pass to the filter 50 and high conductance flow control valve 54, for fluid dispensing.

In such manner, the heating is targeted to a small section of solid material. Such targeting of the heating action on a specific region of solids can also be effected by pushing solids upwardly against a stationary porous or perforated plate member, e.g., by an up-conveying mechanical feeder unit. Alternatively, the solid source material may be disposed in a vessel that itself is translated into a heating zone such as a furnace or oven. In these alternative arrangements, only one heating zone is required. However, it is to be recognized that regardless of whether there is one or a multiplicity of heating zones for volatilization of the solid source material, any heating zone in proximity to the solid material must be cooler than regions downstream of the solid material, in order to avoid condensation of the vapor and unwanted re-deposition of solids in the downstream regions.

In the dispensing of fluid, the vapor from the source solid flows through the valve 54 and discharge fitting 60 into fluid dispensing line 62 containing flow control unit 64 therein. The flow control unit 64 is a schematic representation of componentry that is employed in the dispensing flow circuitry, such as for example, mass flow controllers, temperature and pressure sensors, flow control valves, fluid pressure regulators, restricted flow orifice elements, etc.

The dispensed fluid then flows in dispensing line 62 to the processing facility 66, which may for example include a semiconductor manufacturing tool or other facility in which the dispensed fluid is utilized. The fluid utilization in the processing facility 66 may produce an effluent that is discharged in line 68 to effluent abatement complex 70, wherein the effluent is abated to render it safe or otherwise appropriate for discharge in line 72.

The vessel 12 may be changed out of service when the solid source material is fully depleted. The shaft 22 then can be retracted so that the plate member is above the elevation of the solids fill port 44 on the sidewall 34 of the vessel. The solids fill port can then be opened and the vessel then recharged with solid source material, and the vessel after resealing of the fill port 44 can be returned to service for dispensing of fluid deriving from the solid source material. As a further alternative, the top wall 36 of the vessel 12 may be constructed to be removable from the remainder of the vessel, whereby such top cover is able to be removed for reloading of the vessel interior volume with fresh solid source material. For such purpose, the top cover may be fabricated with a flange member, that is cooperatively matable with a corresponding flange member at the upper end of the sidewall 34, e.g., with the respective flanges being secured by detachable fasteners or coupling members, such as bolt and nut assemblies, to facilitate such removal of the top cover.

Upon removal from service, at the conclusion of the volatilization operation, the vessel can be subjected to appropriate cleaning and renewal operations, to restore the vessel for resumption of operation, by recharging the vessel with new solid source material. The minimization of down-time for such transitional cleanup and recharging operations may be effected by use of a disposable liner that is dropped into the vessel with a fresh inventory of solids, after a prior inventory of solid is volatilized, and the disposable liner previously containing the original charge of solid source material is simply removed from the vessel, and discarded. Such disposable liner is a separate aspect of the present invention.

The use of a liner therefore facilitates the refilling of the vessel. In many instances, after the solid source material is heated for a prolonged period of time, a non-volatile residue may form. This residue, when present on internal wall surfaces of a vessel holding the solid source material, is extremely difficult to remove. Therefore, the use of a disposable liner or bag can greatly enhance the reusability of the solid source vessel.

The vessel may in fact be supplied to a user by the manufacturer or distributor in a closed state, and the vessel, although connected to valves and dispensing lines, may otherwise remain in a closed condition for return to the manufacturer for refurbishing. The manufacturer then may open the vessel for cleaning. If a liner or bag is used, the manufacturer can simply open the vessel, remove and discard the bag, insert a new bag containing a charge of the solid source material, or a bag that is installed in the vessel in an empty state, and then charged with the solid source material.

As another variant, the liner, instead of being disposable, may be formed of a material that is readily cleaned, whereby a liner bag, rather than being discarded, may be simply placed into a volume of cleaning solution, whereby deposited solids, etc. are solubilized or chemically reacted by the cleaning solution, to regenerate the bag for reuse.

The disposable or otherwise reusable liner can be formed of any suitable material of construction, e.g., a polymer such as polyimide, polysulfone, etc. that possesses good structural integrity and retention of properties under elevated temperature volatilization conditions to which the solid source material must be subjected to form the desired vapor.

Solid source material vessels in the systems of the present invention may be provided with a level sensor to provide output that is indicative of the inventory of solid source material in the vessel. In one embodiment, the level sensor includes an inert gas supply that is coupled to the vessel with a flow circuit for pulsing the vessel with a known volume of the inert gas, and a pressure transducer is arranged to make a corresponding pressure measurement of the pressure in the interior volume of the solid source material vessel, to produce a pressure response signal indicative of the amount of solid chemistry remaining in the vessel.

Alternatively, the amount of inert gas that is injected to raise the pressure in the interior volume of the solid source vessel to a given value also provides the same information of how much solid chemistry remains in the vessel. In this case, a mass flow controller could be employed to meter the inert gas into the solids source vessel.

In each of these level sensing arrangements, the level testing operation is conducted when the vessel is isolated from the fluid-utilizing process that is served in normal operation by the vessel. For this purpose, the solid source vessel could be operated so that it is briefly taken off line during normal dispensing operation, to accommodate the level sensing testing. To enable such testing without cessation of supply of vapor to the downstream fluid-utilizing process, the system may be configured with a surge tank, or hold-up volume, to provide a make-up amount of the vapor during off-stream level sensing testing of the solid source vessel.

In still another alternative arrangement, if the solid source material is heated to its melting temperature in the vapor dispensing operation, a float switch can be employed to sense liquid level of the liquefied source material in the supply vessel, to provide an indicative output of the amount of solid source material (in liquefied form) in the vessel.

As a still further alternative arrangement, sensing of the amount of inventory of solid source material (or liquid material, if liquefied) remaining in the vessel can be carried out by use of a flow totalizer, which operates to totalize the flow rate data from a flow controller that is employed to modulate the flow of the vapor from the supply vessel.

In yet another arrangement, the solid source vessel can be fabricated to accommodate a level sensor that senses the position of the plate member 16, to provide an output indication of the amount of the solid source material that is present in the vessel, and remaining to be volatilized and dispensed. In one embodiment, such level sensor includes one or more than one level switches in the wall of the solid source vessel that are engaged when the plate member 16 passes the switch. In another embodiment, the level sensor includes a laser that may for example be mounted in the cover of the solid source material vessel, and arranged to generate a beam of light that is reflected to a detector in an arrangement enabling the detector to output a signal that is correlative to the position of the plate member in the vessel's interior volume. By these arrangements, the level of the solid source material in the vessel can be monitored, and an output generated, e.g., in the form of data stored in a central processor unit (CPU), and/or in the form of a visual and/or audible alarm when the vessel's content of solid source material is approaching depletion and the vessel needs to be changed out and replaced by a fresh vessel.

As another approach that may be employed to monitor the inventory of solid source material in the vessel, the vapor generation system may be constructed and arranged to allow vapor derived from the solid to flow through the shaft 22, with the post in turn communicating with the high conductance flow control valve 56. In this embodiment, there would be no heat transfer fluid in the shaft 22. This arrangement allows the interior volume 14 to be monitored by pressure. If the interior volume 14 is free from leaks, then the pressure in such volume will decrease as the solids are utilized and the plate member 16 pushes downwardly. A corresponding pressure signal then could be used to indicate a solids level in the vessel interior volume at any given time during the vapor dispensing operation.

The vessel containing the solid source material can be heated in any suitable maimer, e.g., involving microwave heating, infrared heating, other modes of radiative heating, conductive heating, convective heating, electrical resistance heating, etc. In application to the generation of vapor from a solid source material, as a reagent for manufacturing of semiconductor products, it may be advantageous to heat the vessel remotely from a semiconductor manufacturing tool, so that when a new solid source vessel is installed for vapor dispensing, the vessel is already at a predetermined elevated temperature at the time it is installed. Such arrangement of “at temperature” installation of the vessel may be useful in minimizing start-up and transition time in the semiconductor fab, where maintaining a high percentage of operational “up-time” is critical to the economic viability of the production facility.

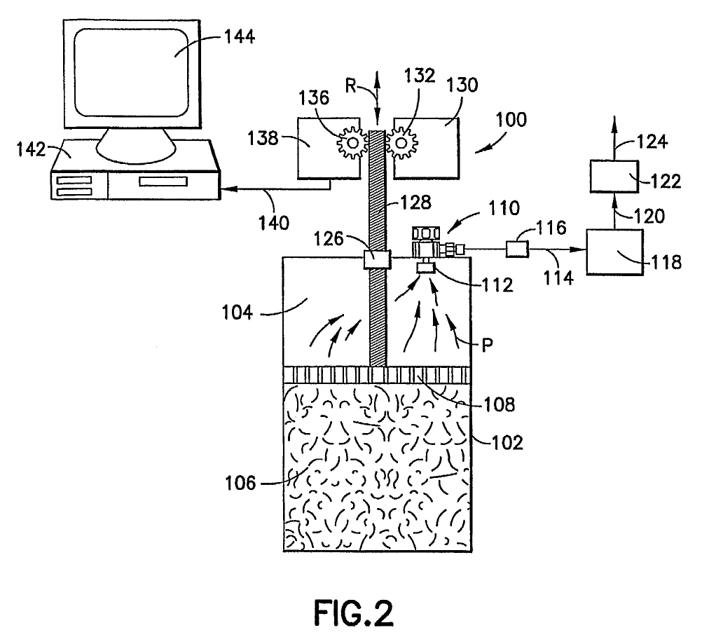

FIG. 2 is a schematic front elevation view in partial cross-section of a system 100 for delivery of reagent from solid source material, in accordance with another embodiment of the present invention.

The system 100 includes a vessel 102 defining an enclosure in which is disposed a quantity of solid source material 106, as a bed or unitary mass in the vessel. In this embodiment, a channelized plate member 108 is mounted on the lower end of a threaded conveyor screw 128 engaged in threaded collar 126 mounted on the top wall of the vessel.

In this embodiment, the conveyor screw 128 is motively driven in a downward manner by the drive gear 132 of the drive unit 130. The drive unit 130 is reversible as regards the rotation of drive gear 132, so that the conveyor screw can be driven in either of the vertically upward and vertically downward directions indicated by bi-directional arrow R. During dispensing operation, the conveyor screw is driven in a downward direction, to maintain pressure on the plate member.

The solid source material 106 concurrently is heated (heating means not shown in FIG.2) in any suitable manner, so that vapor is caused to egress the vessel in the direction indicated by arrow P, flowing through the filter 112, high conductance flow control valve 110, and fluid discharge line 114, having flow control unit 116 therein. From fluid discharge line 114, the vapor deriving from the solid source material enters downstream processing facility 118 for utilization therein.

Such utilization may generate a waste effluent stream, and such stream is flowed in line 120 from the processing facility 118 to abatement facility 122 for treatment, and resulting discharge of a final purified effluent from the system in discharge line 124.

The inventory of solid source material in vessel 102 during dispensing may be monitored by the simple arrangement shown in FIG. 2, wherein the conveyor screw 128 engages a gear 136 of the monitoring unit 138, and according to the rotation of the gear 136 a control signal is generated by the monitoring unit 138 and passed in signal transmission line 140 to CPU 142. The CPU may be of any suitable type, e.g., a general purpose programmable computer, as shown, connected to a monitor 144 for outputting of inventory information in a graphic and/or textual format.

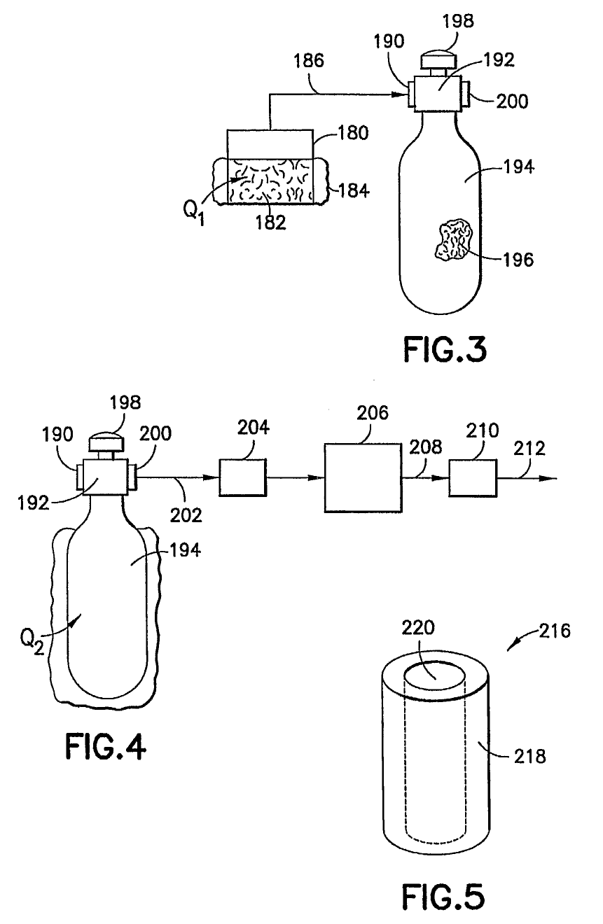

FIG. 3 is a schematic representation of an arrangement for depositing vapor of a solid source material on a physical adsorbent medium in a storage and dispensing vessel. As a further variant aspect contemplated by the invention, the physical adsorbent medium and/or the solid source material can be coated on a high surface area/high thermal conductance medium, e.g., metallic beads, to provide high surface area and high thermal conductivity for the volatilization of the solid source material. By such arrangement, the deficiencies of a lightly-packed powder or monolithic block of the solid source material are overcome.

In this arrangement, the solid source material 182 is contained in a supply vessel 180, having a heating jacket 184 associated therewith, to input a heat energy, Q₁, sufficient to effect sublimation of the source solid material. The resulting solid source material vapor then flows by line 186 to the inlet port 190 of a storage and dispensing vessel 194 containing a bed of physical adsorbent 196, such as activated carbon, molecular sieve, or the like. The sorbent is selected to exhibit sorptive affinity for the solid source material vapor, and the sorbent material therefore takes up the solid source material vapor and retains it in an adsorbed state.

The vessel 194 is as shown equipped with a valve head 192 containing the aforementioned inlet port 190, dispensing port 200 and hand wheel actuator 198.

FIG. 4 is a schematic representation of the storage and dispensing vessel 194 of FIG. 3, in a subsequent dispensing mode, in which the adsorbed source material is desorbed and utilized in a downstream fluid-utilizing process system.

As illustrated, the vessel 194 is disposed in a heating jacket arranged to provide heat input Q₂ to the vessel containing the sorbent loaded with adsorbed solid source material vapor, wherein the heat flux Q₂ is of sufficient magnitude to cause desorption of the sorbate vapor from the sorbent. The valve in valve head 192 is opened by manual movement of the hand wheel 198 to effect dispensing of fluid from dispensing port 200 and flow of the fluid into line 202 containing flow control unit 204 schematically representing flow circuitry and monitoring and control componentry, to the fluid-utilizing facility 206, wherein the fluid is utilized. Such usage may result in generation of an effluent stream that is flowed in line 208 to effluent treatment facility 210 for treatment and discharge in line 212 of a final purified effluent.

FIG. 5 is a perspective view of a source reagent article 216 according to another embodiment of the invention, including a core body 220, on which is coated a solid source material 216. Such an article may be employed in lieu of sorbent medium as described in reference to FIGS. 3 and 4, whereby a multiplicity of the solid source material-coated articles can be disposed in a storage and dispensing vessel, and selectively heated in situ in the vessel, to liberate vapor from the solid source material coating.

The core body for such purpose may be of any suitable size, shape and conformation. In lieu of the rod shape form shown in FIG. 5, the core body can be spherical, ring or toroidal shaped, cubic, helical, flat ribbon shaped, of mesh form, in the shape of needles, cones, or any other geometric or non-geometric shape or form, which is amenable to heating and release of vapor from the solid source material coating on the core body.

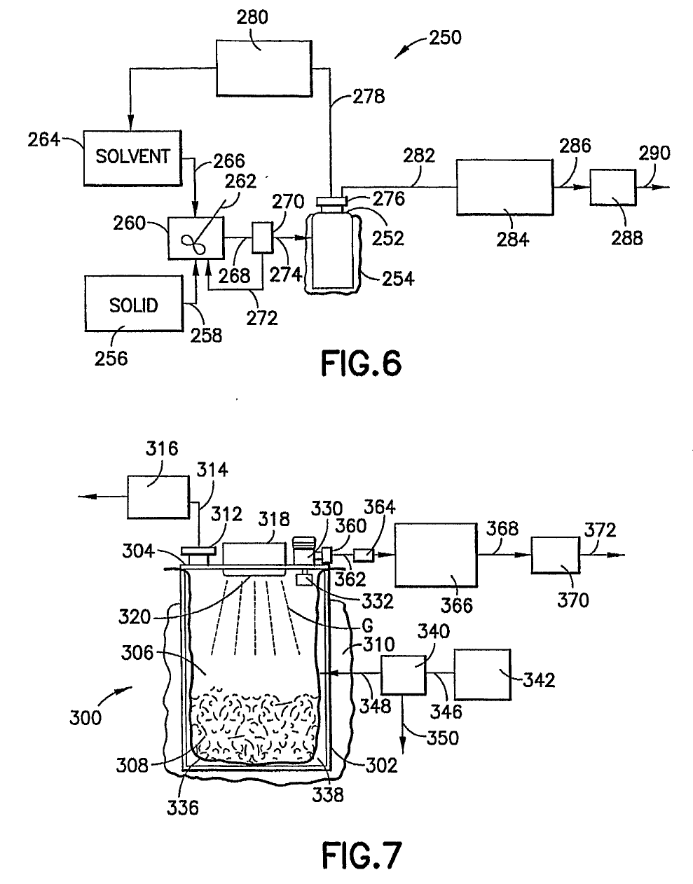

FIG. 6 is a schematic representation of a delivery system 250 utilizing a solid source material, according to yet another embodiment of the invention.

In the FIG. 6 system, a supply vessel 256 of solid source material is arranged for feeding in line 258 of solubilization tank 260 equipped with mechanical stirring schematically shown by impeller 262. The solubilization tank 260 is concurrently fed in line 266 from solvent supply vessel 264 with a solvent that is effective to readily dissolve the solid source material under the mixing conditions obtaining in solubilization tank 260.

The solvent can be readily selected based on solubility data for the solid source material of interest, and volatility data for such solvent. The solvent thus solubilizes the solid source material in the solubilization tank 260, and the resulting solution is flowed from tank 260 in line 268 to the filtration or screening unit 270, which prevents any solids from being flowed forward in the system. Any solids, if present, are collected and recycled in line 272 to the tank 260 for mixing and subsequent resolubilization. Unit 270 may alternatively include a centrifuge, clarifier, sedimentation basin, or other separation unit, by which solids if present are separated for recirculation to the solubilization tank 260.

The resulting solids-free solution then flows in line 274 into the storage and dispensing vessel 252, which in this embodiment is equipped with a heating jacket 254. The vessel 252 may be filled with a bed of support material, such as sorbent particles, and/or non-sorbent media, such as for example in the form of rings, flakes, disks, cylinders, cubes, pyramids, sheets, rods, or other conformation, and such media may include materials that have high specific heat or thermal conductivity, to facilitate the subsequent heating operations, as will now be described.

Once the solution containing the solid source material is deposited into the interior volume of the vessel 276 containing the sorbent or other media therein, the vessel 276 is heated by actuation of the heating jacket 254 to a temperature at which the solvent of the solid source material solution is vaporized to leave the solid source material behind in the vessel (e.g., on and in the pores of the sorbent material or other support, and on the vessel walls). The vaporized solvent is flowed from the vessel 276 into line 278 for flow through chiller/condenser unit 280 to condense the solvent to liquid form. The resulting liquid solvent is thereafter flowed in the recirculation line to the solvent supply vessel 264 for reuse in the make-up of fresh solution of the solid source material.

Once all the solvent has been vaporized and recirculated in the system, the remaining solid source material is left behind in the vessel. The vessel then is heated again to volatilize the solids source material in the vessel, so that the resulting vapor flows out of the vessel in line 282 to the fluid-utilizing facility 284.

In order to accommodate the respective heating steps for separating the solvent in the first step and volatilizing the solid source material in a second step, lines 278 and 282 are suitably valved to direct the respective solvent and solid-derived vapor into the appropriate lines during the sequential heating steps.

The utilization of the solid source material vapor in the facility 284 may produce an effluent requiring treatment, and such circumstance is accommodated by the provision of effluent line 286 that conveys effluent to treatment facility 288 from which a purified final effluent is discharged in line 290.

FIG. 7 is a reagent delivery system 300 utilizing a solid source material 308, according to a further embodiment of the invention.

In the FIG. 7 system, the solid source material containment vessel 302 holds a bag 336 of solid source material 308. The upper free end of the bag 336 is folded over the upper end of the vessel 302, and held in place by the cover 304 for the vessel. The vessel 302 is circumscribed by a heating jacket 310 that is selectively actuatable to heat the vessel and the bag in its interior volume 338.

The cover 304 has mounted thereon a heating unit 318 that includes an infrared heating lamp 320 on the underside of the cover, which impinges IR rays G on the bed of solid source material 308 contained in the bag 336. As an alternative to the use of IR radiation, a laser could be employed as a source of coherent light radiation for very selective heating of the solid source material to generate vapor. Regardless of the specific modality used for effecting heating, the solid source material as a result of heating generates vapor that rises through the headspace 306 in the bag, and passes through filter 332, high conductance flow valve 330, and dispensing fitting 360, and into discharge flow line 362 containing flow control unit 364. Thereafter, the dispensed solid source material vapor flows into the utilization facility 366, with waste effluent therefrom flowing in line 368 to treatment facility for production of treated effluent discharged from the system in line 372.

The vessel 302 has a port 312 on its cover. A vacuum line 314 coupled to vacuum pump 316 may be joined to the port 312, to effect evacuation of gas from the vessel prior to heating to generate the vapor of the solid source material. Alternatively, the flow may be reversed in line 314, to flow a carrier gas or other fluid into the vessel, to facilitate the production of solid source material vapor. Any such carrier gas or added fluid may be heated to introduce sensible heat into the vessel to aid in the sublimation of the solid source material.

The bag 336 in the FIG. 7 system can be made of any suitable material of construction, such as polymer, metal, resin-coated textile fabrics, etc. In a preferred embodiment, the bag is formed of an aluminized or otherwise metallized film material, so that it reflects the IR radiation impinged onto the solid source material in the operation of the FIG. 7 system. The bag may constitute a disposable or reusable liner, which as discussed hereinabove may be discarded or else subjected to a cleaning and renewal operation, e.g., by immersion in a suitable cleaning solution for a period of time appropriate to remove solids deposits and other residue from the sheet or film material of the bag.

As another and optional feature, the solid source material in the bag may be agitated or shaken, by the expedient of pulsing argon, nitrogen or other suitable gas into the space between the bag and the sidewall, so that the bag is deformed to mix the solid source material in the bag and maximize the generation of vapor from the solid source material. For this purpose, a gas supply 342 may be coupled with a reversing pump 340 by means of gas supply line 346. The pump 340 is operated in reciprocating fashion, so that the gas is injected in line 348 between the bag and the sidewall of the vessel, and then gas is withdrawn from such space (between the bag and the sidewall) by pumping such gas out of the vessel for discharge from the pump in discharge line 350. In this manner, the bag is subjected to repetitive, alternating compression and suction, whereby the bag contents are continually mixed to maximize the generation of vapors from the solid source material.

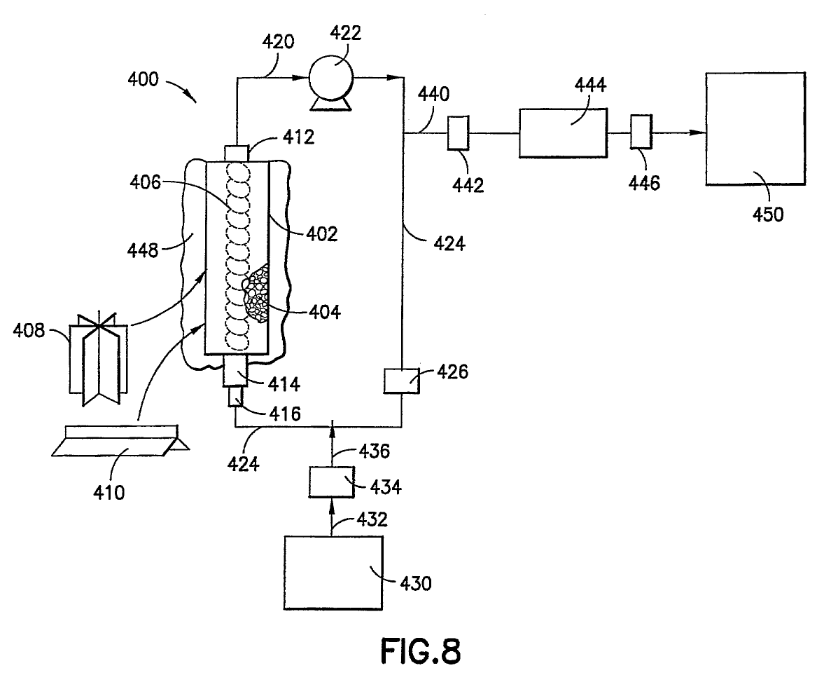

FIG. 8 is a reagent delivery system 400 utilizing a solid source material, in an additional embodiment of the invention.

The FIG. 8 system includes a vessel 402 containing a bed 404 of solid source material particles. As one of several variants, the vessel may have disposed therein a mixing screw 406 coupled with a drive assembly 414 therefor. The drive assembly may for example include a motor and associated gearing for rotation of the mixing screw 406 about its longitudinal axis, so that the solid source material in the vessel is continuously mixed in the operation of the vessel, with heat being input from heating jacket 448, to maximize the generation of vapor, and prevent thermal inhomogeneity in the bed of solid material particles.

Alternatively, or additionally, the vessel 402 may have disposed therein vertically extending heat transfer fin assembly 408 and/or horizontally extended heat transfer fin assembly 410, to maximize solid conduction in the bed of solid source particles.

The vapor generated from volatilization of the solid source particles in the vessel 402 is discharged from the vessel in line 420, under the impetus of the recirculation pump 422, which discharges vapor into the recirculation loop 424 for recycle to the vessel 402, with a portion of the flow being extracted from the recirculation loop 424 and flowed in line 440 containing pressure sensor 442, mass flow controller 444, and temperature sensor 446, to the semiconductor manufacturing tool 450.

The recirculation loop 424 is fed with carrier gas supplied from an inert gas supply 430, from which inert or other carrier gas is flowed in line 432 to the regulator 434 for fluid pressure regulation of such carrier gas flow, and discharge in line 436 to the recirculation loop.

After injection into the recirculation loop 424, the carrier gas flows into the in-line heater 416 for heating thereof to maintain the temperature of the solid source material in the vessel substantially homogeneous, and the carrier gas then is flowed to through the vessel 402.

The pump 422 in the recirculation loop 424, together with injection of carrier gas into the recirculation loop, creates a pressure head prior to the mass flow controller 444, which allows the mass flow controller to operate more effectively than if pure vapor of lower pressure were to be delivered to the tool through the mass flow controller. When the mass flow controller opens, the pressure in the recirculation loop 424 will drop, thereby pulling in more carrier gas. This will tend to maintain a constant pressure before the mass flow controller.

The recirculation loop 424 may as shown have a check valve 426 therein before the carrier gas inlet. Instead of a mass flow controller 444, the system alternatively may employ a simple orifice, so that the flow of source chemistry is controller by controlling the pressure within the recirculation loop 424.

The system of FIG. 8 is operated with a major part of the carrier gas/chemistry mixture discharged from the vessel into line 420 being recycled back to the vessel 402. This ensures that the carrier gas will contain a chemistry component nearly equal, if not equal, to the equilibrium vapor pressure of the chemistry component, e.g., decaborane.

The temperature sensor 412 at the outlet of vessel 402 and the pressure sensor in line 440 may be integrated in a monitoring and control scheme that serves to modulate the heating of the in-line heater 416 and the heating jacket 448, to achieve a predetermined temperature and pressure of the flow of source solids chemistry being introduced to the tool 450 from line 440.

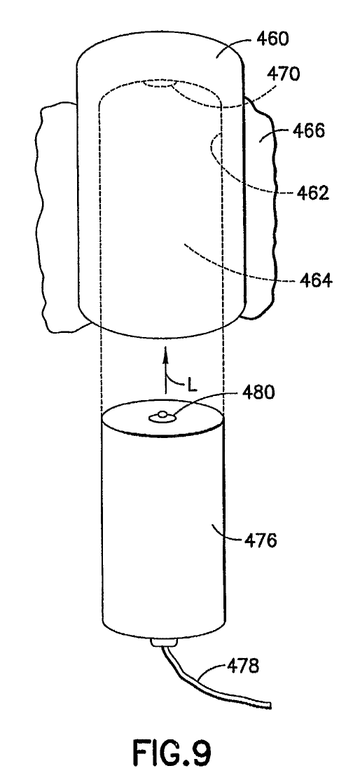

FIG. 9 is a perspective schematic view of an annular-shaped reagent dispensing vessel 460 according to a further aspect of the invention, accommodating an interior positioning of a heating insert 476, as well as a heating jacket 466 on exterior surface thereof.

The annular shaped vessel 460 is annular shaped with a interior cavity 464 defined by an annular interior wall 462 of the vessel. The ports or vapor discharge passages of the vessel have not been shown in FIG. 9 for ease of description. The vessel contains a charge of solid source material, and the interior cavity 464 is shaped to accept a correspondingly shaped heating insert 476, which may have a power cord 478 enabling the insert unit to be plugged into an electrical power supply to effect electrical resistance heating by the insert of the vessel 460.

The heating insert 476 thus is inserted upwardly in the view shown in FIG. 9, into the cavity 464 of the vessel 460. The vessel cavity is provided with a registration coupling 470 which cooperatively mates with the complementarily shaped registration element 480 on the top surface of the heating insert. Such complementary mating structure 470, 480 thus ensures that the heating insert and vessel are appropriately positioned before heating by the insert of the vessel is initiated. In one embodiment, the mating structure 470, 480 may be arranged so that the heating insert is prevented from operating unless the registration element 480 and registration coupling are engaged with one another.

The vessel 460 also may have an exterior heating jacket 466 applied to its exterior surface, whereby the annular walls are most effectively heated to generate vapor from the solid source material in the vessel.

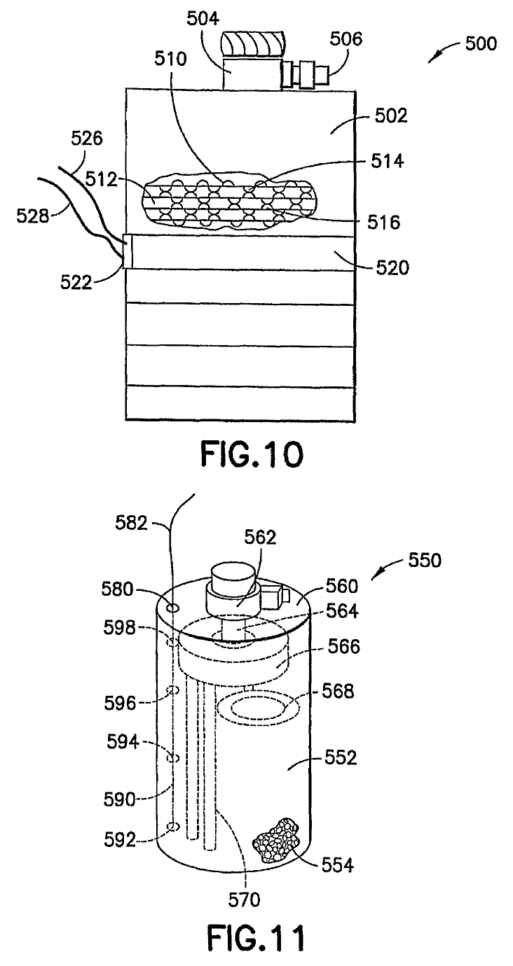

FIG. 10 is an elevation view in partial section of a reagent delivery vessel 500 according to one embodiment of the invention, featuring a series of horizontal trays 510, 512 in stacked arrangement, in which each tray is coated with or contains a solid source material.

The vessel 500 as illustrated has a cylindrical circumscribing wall 502 and is equipped with a dispensing valve 504 coupled with a suitable dispensing fitting 506 for connecting the vessel to dispensing flow circuitry. The vessel in its interior volume contains a stacked array of trays 510, 512 coated with or otherwise containing the solid source material. The trays in the illustrated embodiment are provided with protrusions thereon which mate with protrusions on an adjacently positioned tray, to provide an array of stacked trays. The trays in the stacked array may be formed of any suitable material of construction, but preferably are formed of a high thermal conductivity material, e.g., aluminum, copper, nickel, etc.

The vessel 502 is heated by an electrical heating tape 520, which is serially wrapped about the vessel as shown, and terminates in a free end 522 having electrical resistance heating wires 526 and 528 extending therefrom for coupling with a power supply or other source of electrical energy, to effect heating of the tape, and thereby of the vessel. As a result, the vessel is heated and the trays therein effectively conduct heat to the solid source material on or in the trays, to generate vapor for dispensing from the vessel. As another alternative, the vessel 502 could be heated by a molded heating jacket that conformably mates with the vessel, in intimate heat transfer contact therewith.

FIG. 11 is a perspective view in partial section of a reagent delivery vessel 552 according to a further aspect of the invention, incorporating an internal fluid collection manifold 566 associated with porous tubes 570 and/or porous rings 568.

The system 550 of FIG. 11 includes vessel 552 of a generally cylindrical shape, with a top wall 560 on which is mounted a dispensing valve 562 that is coupled by connecting tube 564 to the manifold 566, formed as a cylindrical shaped interior vessel that in turn connects with the porous tubes 570 and porous rings 568. The purpose of the porous tube and ring members is to accommodate the inflow of the vapor from the solid source material upon heating thereof. The solid source material 554 is contained in the interior volume of the vessel 552, surrounding the porous tube and ring members therein.

In this embodiment, a thermocouple 590 is disposed in the bed of solid source material, and provides spaced apart sensors 592, 594, 596, and 598 along its length, for monitoring the temperature of the bed along its entire height, so that heating (by means not shown in FIG.11) can be modulated as necessary to provide the desired level of vapor generation from the source material. The thermocouple 590 passes through the top wall 560 of the vessel at seal 580 and terminates in an exterior portion 582 that is coupled to a suitable controller/recorder device to assist monitoring and control of the vapor generation operation.

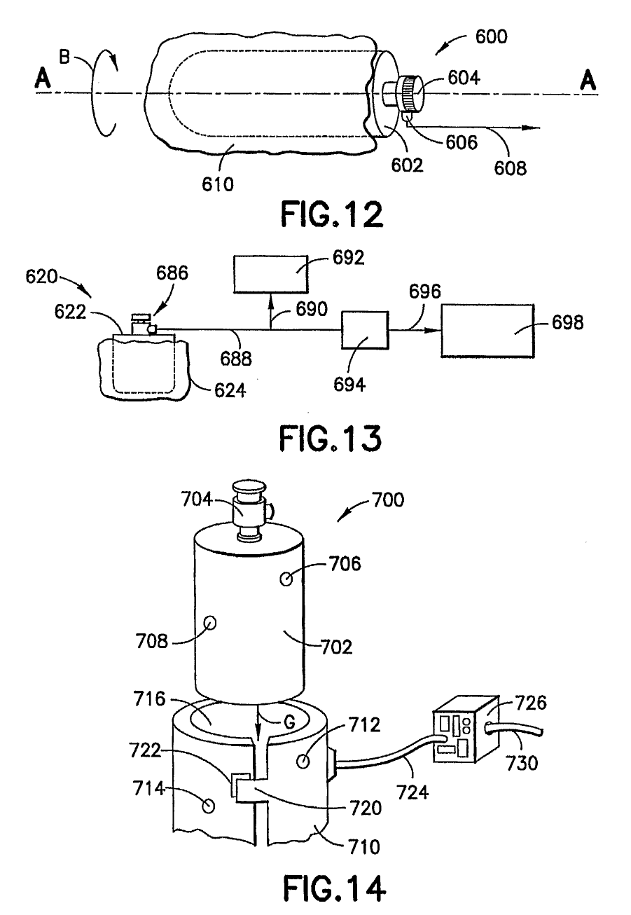

FIG. 12 is a schematic representation of a horizontally oriented reagent delivery vessel 600 illustrating a solids volatilization technique according to a further aspect of the invention. The vessel 600 is encased in a heating jacket 610 with its top wall 602 having dispensing valve 604 thereon, with dispensing fitting 606 being arranged for coupling with dispensing line 608 as illustrated.

The horizontal orientation of the vessel in the embodiment of FIG. 12 is advantageous inasmuch as it permits gravitation force to keep the lower portion of the vessel wall in such position in contact with source solid material. As the material in contact with such wall portion is volatilized, the vapor passes away from the wall and is displaced by solids that then fall into contact with the wall at the lower portion of the vessel in such horizontal orientation. As a further variation, the vessel shown in FIG. 12 could be arranged for rotation about its horizontally aligned longitudinal axis A-A, in the direction of rotation shown by arrow B, to ensure that the solid source material in the vessel is continuously agitated and mixed, to ensure thermal homogeneity of the solid material in the vessel. In such rotary mode, the vessel may employed suitable rotary seals and couplings, of a type known in the art for effecting a fluid-tight seal involving rotating members.

FIG. 13 is a schematic representation of a reagent delivery system 620 according to another embodiment of the invention, featuring a buffer zone.

The system 620 includes a vessel 622 in heating jacket 624 and equipped with a dispensing valve head 686 arranged for dispensing of solid source material vapor into the dispensing line 688 containing flow control unit 694 schematically representing mass flow controller, valve, orifice, sensor, etc. components, as necessary or desirable in the operation of the system. From the flow control unit 694, the vapor derived from the solid source material is flowed in line 698 to the vapor-utilization unit, e.g., a semiconductor process tool.

The system 620 of FIG. 13 includes a buffer vessel 692 that is linked by conduit 690 to the dispensing line 688. The conduit and dispensing line may be valved and arranged as necessary to effect flow of vapor into the buffer vessel 692 during the dispensing operation, when the amount of dispensed vapor is adequate to such buffering operation. The buffer vessel is of course appropriately insulated and/or heated to maintain the vapor in fluid form, and to prevent condensation and solidification of the vapor in the buffer vessel.

In this manner, a buffering amount of solid source material vapor is accumulated in the buffer vessel, and is available for flow back into the dispensing line 688 when the inventory of vapor in dispensing line 688 is low or otherwise in need of supplementation. The dispensing of the buffer volume vapor to the dispensing line 688 may be controllably arranged by suitable sensing and monitoring of the vapor generation in vessel 622 and/or vapor consumption at the vapor utilization unit 698.

FIG. 14 is a perspective view of a reagent delivery vessel 702 being inserted into a conformably shaped heating jacket 710, illustrating a further aspect of the invention in another embodiment.

The system 700 shown in FIG. 14 includes a vessel in which solid source material is retained for volatilization thereof. The vessel 702 includes a dispensing valve 704, and thermocouples or other temperature sensing elements 706 and 708 on the vessel wall, as illustrated.

The vessel 702 is shown being lowered in the direction indicated by arrow G into the heating jacket 710. The heating jacket 710 defines therein a cavity 716 for receiving the vessel 702. The jacket is formed to mate with the vessel, and for such purpose the heating jacket may have a molded insert that is conformable to the vessel exterior surface. The heating jacket includes a seam that can be manually opened to facilitate insertion of the vessel into the cavity of the jacket. After the vessel is positioned in the jacket, the complementarily mating closure elements 720 and 722, e.g., Velcro® hook and loop fastener elements, are engaged to positionally retain the vessel in the jacket.

The jacket may have thermocouples or other temperature sensing elements 712 and 722 as shown, or monitoring elements that cooperate with the elements 706 and 708 on the vessel wall, to maintain the heating by the jacket of the vessel at an appropriate level for volatilization of the solid source material in the vessel, during vapor generation and dispensing operation.

The heating jacket 710 is shown as coupled by wire 724 to the heating controller unit 726, which in turn is connected by power cord 730 to a suitable power supply. The heating controller unit 726 is a programmable unit that may be preset to conduct a heating cycle program of desired duration or intervals, and such unit may be integrated with other sensors, monitoring and control equipment in the system to effect a highly efficient volatilization of the solid source material for vapor generation.

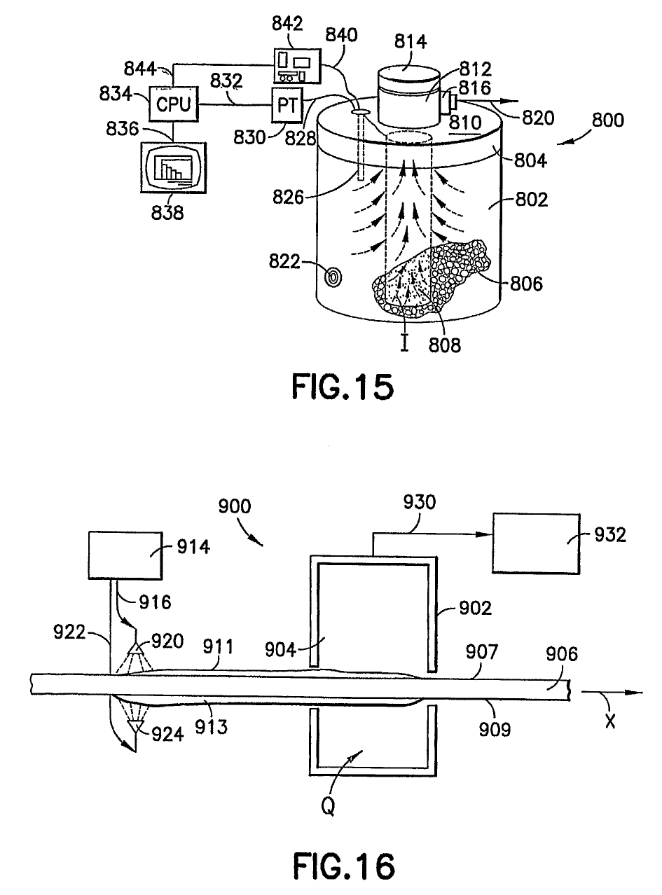

FIG. 15 is a perspective view in partial section of a system 800 including a reagent delivery vessel 802 according to a further aspect of the invention, featuring a collection manifold member coupled to a porous collection tube for discharge of vapor from the vessel, and showing associated monitoring and control componentry.

The system of FIG. 15 includes a vessel 802 of cylindrical form, which mates with a manifold cover 804. The manifold cover 804 defines a hollow interior volume and has mounted on a top surface 810 thereof a dispensing valve 812 to which is coupled a dispensing fitting 816 shown as connected to a dispensing line 820 for discharge of vapor derived from the solid source material 806 contained in the vessel, e.g., in particulate form, as shown.

The vessel 802 features a porous tube 808 coupled with the manifold cover 804, so that upon heating of the solid source material 806 in the vessel (heating means not shown in FIG. 15), vapor flows through the wall of the porous tube and flows upwardly in the direction indicated by arrows I, to enter the hollow interior volume of the manifold cover 804 for subsequent discharge from the vessel when the valve 812 is open for dispensing flow.

The vessel 802 also features a fill port 822, by means of which the vessel may be charged with solid source material and thereafter sealed. The vessel is equipped with a pressure sensor 826, connected by signal transmission line 828 to the pressure transducer (PT) 830, which in turn is connected by signal transmission line 832 to the CPU 834. The CPU 834 is in turn connected by cable 836 to monitor 838 for visual display of data indicative of pressure in the vessel. Alternatively, the sensor 826 may be a temperature sensor, and the pressure transducer 830 may be replaced by a temperature transducer.

The porous tube 808 may as shown by connected by electrical resistance heating wire 840 to a heating controller 842 that functions to provide an appropriate electrical input to the porous tube to heat it to a desired temperature. The heating controller is appropriately powered (power source not shown in FIG. 15), and is connected by signal transmission line 844 to the CPU 834, to enable integrated monitoring and control of the system.

The porous tube 808 thus is heated to appropriate temperature to volatilize the solid source material in the vessel and induce flow of resultant vapor though the interior passage of such tube to the collection manifold of manifold cover 804.

In another mode of operation, the heating of porous tube 808 by the heating controller may be effected so that the solid source material if susceptible to melting as opposed to direct sublimation, may be melted to cause transpiration flow of liquid through the wall of porous tube 808 and the porous tube then can be pulsed with energy input of sufficient magnitude via the resistance heating wire 840 to flash the liquid in the interior passage of the hollow tube 808 to vapor. The pressure sensor 826 can then be employed to sense the resulting pressure, to determine inventory of the solid source material in the vessel as a function of its vapor pressure sensed by the pressure sensor, so that the inventory of the solid source material is monitored, and the vessel 802 is changed out, or operation terminated, at an appropriate point in the operating cycle.

FIG. 16 is a schematic front elevation view, taken in cross-section, showing an elongate support member 906 being coated with a solid source material, and the resultant coated article being translated through a heated zone 900 to volatilize the solid source material to form vapor for a fluid-utilizing installation 932.

The heated zone 900 includes an enclosure 902 enclosing an interior volume 904. The heated zone can be of any suitable type, e.g., a furnace, oven, hot box, thermal chamber, or the like.

The elongate support member 906 in this system may for example be a tape, web, sheet, filament, wire, or other substrate article, which is coated with a powder coating of solid source material particles. In the ensuing description, support member 906 will be taken as a tape having respective top surface 907 and bottom surface 909.

The support member is translated past an array of spray heads including spray head 924 arranged to spray powder supplied to such head in line 922 from powder reservoir 914, and spray head 920 arranged to spray powder supplied to such head in line 916 from the powder reservoir 914. For such purpose, the powder is a particulate form of the solid source material from which vapor is generated when the coating 911 of solid source material on top surface 907 of the tape and the coating 913 of solid source material on the bottom surface 909 of the tape are volatilized when the coated tape is translated through the heated zone 900 (wherein heat introduction is schematically shown by the heat input arrow Q, into the interior volume of the heated zone).

As a result, vapor deriving from the coating of solid source material is collected in the interior volume of the heated zone 900 and is passed in discharge line 930 to the downstream fluid-utilizing facility 932, which may for example include a semiconductor manufacturing facility.

Thus, the coating on the respective top and bottom surfaces of the tape 906 is removed by volatilization in the heated zone 900, and the resulting tape, returned to an uncoated state, is translated in the direction indicated by arrow X out of the system. The tape may be a discrete length of web or sheet stock material that is processed through the coating and heated volatilization zones, or alternatively, the tape may be formed in an endless loop, so that the tape after passage through the system as schematically shown in FIG. 16 is returned to the coating zone and recoated with solid source material powder.

To facilitate the coating operation, the solid source material powder may be formulated with a volatile binder or carrier or other matrix material to lend consistency and structural integrity to the coated film of the powder on the substrate article, prior to its entering the heated zone 900. Alternatively, the substrate article can be formed of a material that has an inherent low tack characteristic, to which the solid source material powder is adherent. As a still further alternative, the substrate article may be coated with a low-tack polymer or other adhesive medium, to facilitate the adherence of the solid source material powder to the substrate article surfaces.

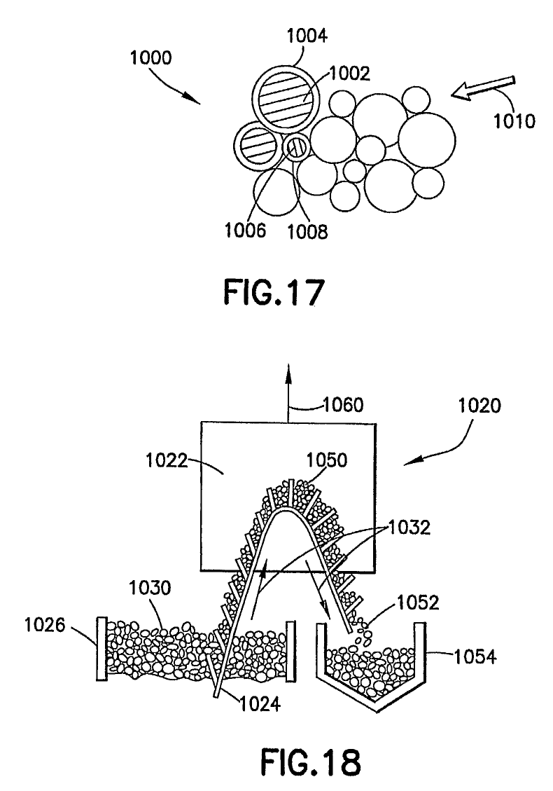

FIG. 17 is a schematic illustration of a mass 1000 of adsorbent particles and high thermal conductivity particles in admixture, and depicting some of the adsorbent and high thermal conductivity particles in cross-section, to show the coatings thereon of a surface film of solid source material, wherein the mass of particles is being impinged by energy (indicated by arrow 1010) mediating volatilization of the solid source material. The adsorbent particles 1002 in this mass 1000 have a coating 1004 thereon of a solid source material, e.g., in a thin film form. The high thermal conductivity particles 1006 in the mass 1000 also have a coating 1008 thereon of the solid source material, e.g., in thin film form.

By such conformation, the particles of the adsorbent and the high thermal conductivity material in the mass 1000 provide a high surface area to volume amount of the solid source material, which since it is in thin film form on the surface of the adsorbent and high thermal conductivity particles, as well as in the porosity of the adsorbent, is readily volatilized in a highly efficient manner.

The particles in the mass 1000 may be coated in any suitable manner, e.g., by roller coater techniques, spraying, dipping, fluidized bed coating, or any other manner imparting the coating to the particles. The adsorbent can be of any suitable type, e.g., an activated carbon adsorbent, molecular sieve, kieselguhr, clay-type sorbents, macroreticulate resins, silica, alumina, etc. The high thermal conductivity particles in the mass can be of any high conductivity material, but preferably are formed of a metal, such as for example nickel, stainless steel, titanium, etc., or a high thermal conductivity ceramic.

FIG. 18 is a schematic representation of a conveyor system 1020 for translating particles 1030 of solid source material through a heated zone 1022 to volatilize the solid source material and form a vapor for use in a vapor-utilization process.

As illustrated in FIG. 18, a supply vessel 1026 containing the particles 1030 forms a reservoir for pickup of particles by the conveyor 1024 equipped with flaps, scoops or other pick-up structure on the main face thereof. The conveyor 1024 is translated in the direction indicated by arrow 1032 through a heated zone 1022, wherein the particles 1050 carried by the conveyor are at least partially volatilized in such zone, to generate vapor. The vapor is discharged from the heated zone 1022 in line 1060 for subsequent use.

The partially volatilized particles 1052 are carried by the conveyor to the collection chamber 1054. The collection chamber 1054 may be arranged in feed relation to the supply vessel 1026 for recirculation of the particles so that they are eventually fully volatilized by recycle passage through the heated zone 1022.

Alternatively, the particles in the FIG. 18 system can be substrate particles, e.g., of the type or types shown and described with reference to FIG. 17 herein that have been coated with the solid source material.

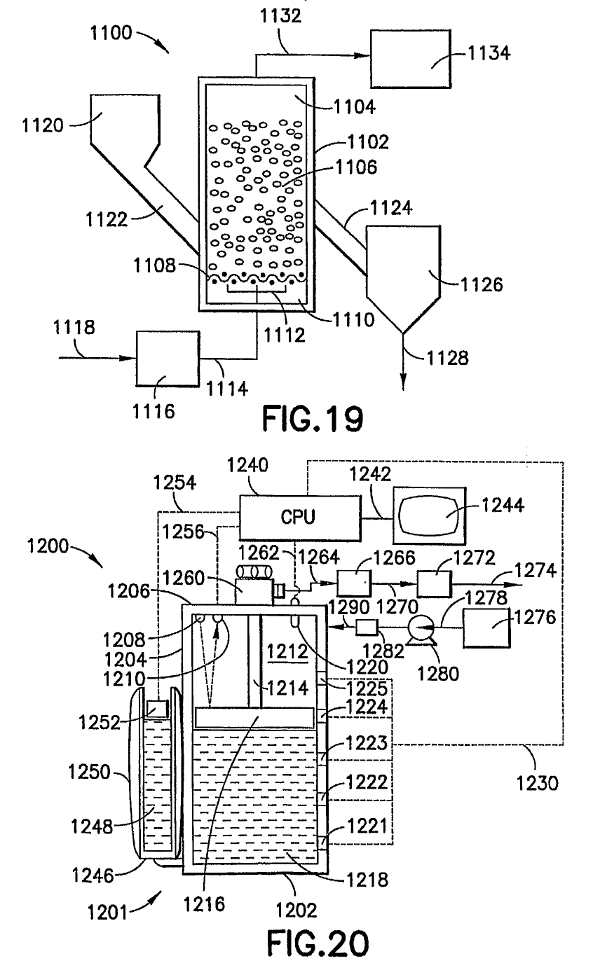

FIG. 19 is a schematic representation of a fluidized bed system 1100 for generating vapor from solid source material coated on substrate particles, and for utilizing the resulting vapor in a downstream fluid-utilization facility 1134.

The system 1100 includes a fluidized bed vessel 1102 enclosing an interior volume 1104 having a fluidized bed 1106 of particles therein, above a screen support 1108. Below the screen support 1108 is a gas distributor 1112 positioned in the lower plenum space 1110 of the vessel. The gas distributor 1112 is joined by gas feed line 1114 to a source 1116 of fluidizing gas, e.g., air that is collected in intake line 1118 for purification and compression, and then flowed to the vessel 1102 in line 1114.

The vessel 1102 is joined in solids feed relationship to a feed hopper 1120 from which particles coated with solid source material flow in chute 1122 into the fluidized bed 1106. A take-off chute 1124 is provided on the opposite side of the bed, connected to the collection hopper 1126, from which spent solids may be removed in line 1128 for treatment, reclamation, or other disposition.

Vapor deriving from the volatilized solid source material, as generated in the fluidized bed, operated at elevated temperature appropriate to the volatilization, is discharged from the fluid bed vessel in line 1132 and flows therein to the fluid-utilization facility 1134.

By the arrangement shown in FIG. 19, the residence time of the solid source material-coated particles in the hot fluidized bed can be controlled to maximize the generation of vapor in a thermally efficient manner.

FIG. 20 is a schematic representation of a vapor-generation system 1200 utilizing a solid source material, accessorized with various monitoring and control components.

As shown in FIG. 20, the vapor-generation system 1200 includes a vapor-generation vessel 1201 having a floor 1202, a cover 1206, and a circumscribing side wall 1204 defining a closed interior volume 1212 therein. In such interior volume 1212 is contained a quantity of initially solid source material 1218 that may for example be in a liquid or semisolid form, owing to heating of the solid source material (heating means not shown in FIG. 20). The solid source material 1218 is overlaid by a porous plate member 1216 secured at the lower end of a shaft 1214, as shown.

In the arrangement shown in FIG. 20, the shaft 1214 may be hollow to accommodate flow therethrough of vapor to the high conductance flow control valve 1260, for discharge from the valve 1260 into line 1264. The vapor flows in line 1264 to the flow controller 1266, from which the vapor flows in line 1270 to the flow totalizer 1272, being thereafter flowed in line 1274 to a fluid-utilizing facility or process tool. The flow controller 1266 can be of any suitable type, including for example flow control valves, mass flow controllers, restricted flow orifice elements, fluid pressure regulators, etc.

The flow totalizer can be used to determine the cumulative amount of vapor that is flowed from the vessel 1201, and thereby provide an output indicative of the amount of the source chemistry remaining in the vessel. The totalizer can be arranged to output a signal, e.g., an audible and/or visual alarm, when the source chemistry in the vessel is approaching exhaustion, and the vessel needs to be recharged with fresh source chemistry, or otherwise changed out for a fresh vessel containing source chemistry.

In addition to the totalizer, the level of the source chemistry in the vessel 1201 can be determined in a variety of ways in the system of FIG. 20. The system can for example have a side chamber 1246 coupled in flow communication with the vessel 1201, in which source material 1248 is maintained in a liquid or flowable semisolid form by heating supplied to the side chamber by the heating jacket 1250. A float sensor element 1252 is disposed in the side chamber and operatively linked by signal transmission line 1254 to the central processor unit (CPU) 1240, to enable a signal to be sent from the float sensor to the CPU for monitoring of the level of source chemistry material in the side chamber.

The CPU can be of any suitable type, e.g., a general purpose programmable computer, a microprocessor unit, a programmable logic controller, etc. Linked in output relationship to the CPU 1240 by signal transmission line 1242 is an output display 1244, for graphical outputting of visual data, such as a graphic depiction of the vessel 1201 showing a level of the source chemistry therein.

As another modality for level monitoring of source chemistry in the vessel 1201, the cover 1206 of the vessel can have mounted on the underside thereof a laser signal generator 1208 that emits a laser signal. The laser signal emitted from the generator 1208 is impinged on the top surface of the plate member 1216 and reflected to the optoelectronic detector 1210 on the underside surface of the cover 1206. The optoelectronic detector 1210 responsively transmits an output signal, indicative of the distance from the detector to the top surface of the plate member, in signal transmission line 1256 to the CPU 1240, for monitoring of the level of the source chemistry, and outputting of a graphical depiction of the level on monitor 1244, and/or maintaining a data log of the level and providing an output indicative of the approach of exhaustion of the source chemistry in the vessel 1201.

As a further variant of level sensing of the source chemistry in the vessel 1201, the vessel may be equipped with a series of vertically spaced-apart proximity switches 1221, 1222, 1223, 1224 and 1225 as mounted in the sidewall 1204 of the vessel and operatively linked by signal transmission line 1230 to the CPU 1240. Each proximity switch is actuated by contact or proximity of the plate member 1216, so that as the plate member is lowered progressively during the dispensing of vapor from the vessel, it actuates each of the successively lower switches to send a corresponding signal indicative of such position to the CPU for monitoring and outputting of an output enabling an operator to be informed of the location of the plate member in the vessel. This in turn permits timely action to be taken to recharge the vessel with fresh source chemistry, or to change out the vessel for a fresh vessel.

The system 1200 also includes a dynamic testing assembly for determining the level of the source chemistry in the vessel when the vessel is not actively dispensing vapor to the downstream fluid-utilizing process. A source 1276 of inert gas, e.g., nitrogen, helium, argon, or the like, is joined by supply line 1278 to the pump 1280, which functions to inject a bolus of inert gas into the feed line 1290 containing mass flow controller 1282 therein, so that inert gas is injected in turn into the interior volume 1212 of the vessel 1201. A pressure transducer 1220 is mounted on the cover 1206 of the vessel and is linked by signal transmission line 1262 to the CPU 1240.

In operation, the pump 1280 is actuated to pulse (inject) the vessel 1201 with a know volume of inert gas from the source 1276. The pressure transducer 1220 then can be used to determine the available open volume in the vessel, which is related to how much source chemistry material remains in the vessel, which can be algorithmically determined by the CPU 1240 and outputted as desired.

Alternatively, the system can be arranged so that the volume of inert gas from the source 1276 necessary to raise the pressure (as measured by the transducer 1220) in the vessel 1201 to a specific pressure is determined, and the volume of inert gas can be inputted to the CPU 1240 to determine the amount of the source chemistry that remains in the vessel. For this method, the mass flow controller 1282 can be used to meter the inert gas into the vessel.

In either of the level determination methods described in the last two paragraphs, the determination is made when the vessel is not actively supplying vapor in a dispensing mode. For this purpose, the injection of the inert gas is conducted with the vessel 1201 being off-line. This may be conducted by a cycle timer program administered by the CPU, operatively linked in controlling relationship to the flow control valve 1260, to shut off the valve 1260 when the dynamic level determination is being conducted. The discharge line 1274 can be provided with a surge tank or other hold-up vessel (not shown in FIG. 20) in communication therewith, for take-up of a volume of surplus vapor during the active dispensing operation, so that during the dynamic level testing, the valve 1260 is shut off, and the vapor from the hold-up vessel is supplied to the downstream fluid-utilizing process, to thereby maintain continuity of vapor dispensing operation. The hold-up vessel may be associated with the discharge line 1274 by suitable valve manifolding, bypass lines, or other flow circuitry to effectuate such operation.

It will therefore be appreciated that the present invention provides an efficient and reliable apparatus and method for the delivery of vapor from a solid source material, and that the invention can be practiced in various embodied arrangements including monitoring and control of the dispensing operation, so that vapor is provided to a fluid-utilizing facility or process in a safe and effective manner.

In another aspect, the solid source reagent delivery system includes a vessel defining an enclosed interior volume in which the solid source material is retained. The vessel is equipped with a valve assembly at its upper end that is enveloped by a block of high thermal conductivity material such as aluminum that can be detachably secured to the valve assembly. The block is separable into component parts, which cooperatively mate with one another to form the enveloping block structure around the valve.

For example, the block in one embodiment is formed of two half-sections that envelope the valve assembly, in thermal conduction contact with the valve structure, so that the block when heated thermally conducts heat to the valve, to avoid condensation of the solid source reagent vapor in the valve assembly.

The respective parts of the block may be coupled with one another in any suitable manner. For example, the block may be formed as half-sections that are hinged with respect to one another, to be opened and fitted around the valve head assembly, being thereafter closed so that the half-sections mate with one another and are secureable in position by a suitable securement structure.

This securement structure may be of any suitable type, including coupling elements, lock structures, latches, keyed structures, etc. The block may be equipped with a passage therethrough to permit flow of source reagent vapor from the valve in the valve assembly through the block to associated flow circuitry. The flow circuitry can in turn be coupled with a downstream process facility in which the dispensed vapor is utilized.

For such purpose, the block may be equipped with fittings, couplings, or the like that matably engage the port of the valve in the valve assembly, and permit coupling of the block with the associated flow circuitry, e.g., a discharge conduit with a fitting that engages the block.

The block may be heated by any suitable heating arrangement, including radiant heat, resistive heating of the block itself when coupled with a suitable electrical power supply, impingement of microwave or ultrasonic energy on the block causing heating thereof, jacketing of the block with a heating jacket operatively arranged to heat the block to elevated temperature, or other suitable heating arrangement by which the temperature of the block may be elevated to conduct heat to the valve passages in the valve assembly of the solid source reagent dispensing system, so as to prevent condensation of source reagent vapor in the passages of the valve and associated flow circuitry.

In another aspect, the invention relates to a solid source reagent delivery system including a flange serving to close the vessel of the delivery system, in which the flange is secured to the reagent supply vessel by non-standard screws requiring a special tool to disengage, such as a non-standard screwdriver. In such manner, the reagent delivery system is rendered tamper-resistant or tamper-proof in character.

In another embodiment, screws employed to secure the flange to the vessel have labels placed thereover, so that the labels have to be broken in order to obtain access to the mechanical fasteners beneath them. Such arrangement insures that any tampering or unauthorized access to the vessel is readily detectable.

In yet another embodiment, the solid source reagent delivery system includes a vessel defining an enclosed volume holding the solid source material, in which the vessel is adapted to employ cartridge heaters, e.g., in the form of thin, cylindrical, resistive heaters or other compact form of heater, on the vessel. For example, one or more than one, e.g., 3 or 4, heaters can be arranged in or near the valve associated with the vessel that is used to control the flow of the solid source vapor from the vessel when the source material is heated in the vessel. The valve can be of a high-conductance character, and can be mounted on the flange or other closure member that is employed to define with the vessel an interior closed volume in which the solid source reagent is stored and from which vapor of the solid source reagent is disepensed from the vessel during dispensing operation thereof.

In one embodiment of the solid source reagent delivery package, featuring a conductive block surrounding the valve as above described, the block may be provided with drilled holes or bores in which resistive heating elements can be inserted, to heat the block and thereby the valve enveloped by the block. Additionally, or alternatively, the vessel itself can be constructed so that heaters can be employed within the vessel wall or adjacent thereto.

For example, the wall of the vessel can be made sufficiently thick to accommodate the formation therein of wall pockets, to accommodate such heaters, which can be selectively inserted into the pockets to provide heating of the vessel wall so that heat is conducted into the vessel for heating of the solid source reagent material therein. The vessel for such purpose may be formed of a conductive material, such as aluminum or an aluminum alloy.

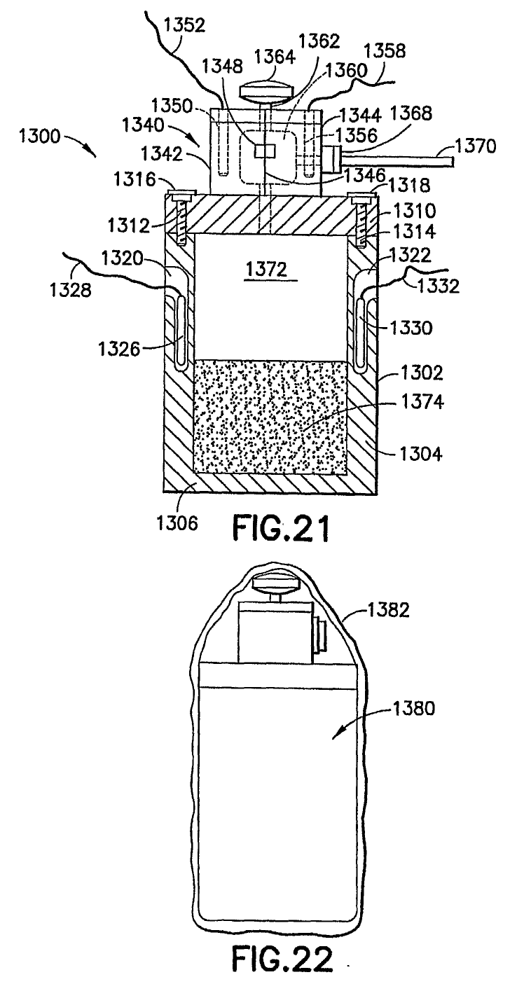

FIG. 21 is an elevation view, in partial cross-section, of a solid source reagent delivery package 1300, according to one embodiment of the invention.

The solid source reagent delivery package 1300 includes a solid source reagent vessel 1302 having a circumferentially extending cylindrical sidewall 1304 and a floor 1306 that together with the top flange closure member 1310 define an enclosed volume 1372 holding solid source reagent 1374. Although the solid source reagent material is shown in FIG. 21 as being provided as a mass of filled material in the vessel, for clarity of illustration, it will be recognized that the material can be provided on a support or other associated structure facilitating the generation of vapor from the solid source reagent. In one particularly preferred embodiment, the solid source reagent material is supported by a porous metal medium, either in a block or monolithic form, or in the form of packing bodies, in the interior volume of the vessel.

The top flange closure member 1310 is provided with threaded passages therein accommodating the respective mechanical fasteners 1312 and 1314, which engage corresponding threaded passages in the sidewall 1302. In this manner, the top flange closure member 1310 is mechanically fastened and secured to the vessel sidewall.

As an anti-tamper feature, the head portions of the mechanical fasteners 1312 and 1314 may be formed so as to require a non-standard screw driver for extraction thereof, or formed in such other manner as to require use of other non-standard tool, so that the tamper-resistant character of the package is enhanced.

As a further feature, adhesive labels 1316 and 1318 may be disposed over the head portions of the mechanical fasteners, whereby any attempted unauthorized access to the contents of the package will be detected by breakage of the label seals.

The top flange closure member 1310 has a central opening therein communicating with a valve assembly 1360 that is encased in the block 1340. The block 1340 is formed of half-sections 1342 and 1344. The respective half-sections cooperatively mate at seam 1346, and are coupled with one another by the fastener 1348 on the front face of the block as shown in FIG. 21. The block 1340 can be formed in half-sections that on the back side of the block are hinged to permit the block sections to open and close, in clam-shell fashion, to engage the valve assembly 1360 in thermal contact therewith.

The block 1340 may be provided with passages therein that communicate with a valve chamber (not shown) in the valve assembly, in which a valve element (likewise not shown) joined to valve stem 1362 may be translated by rotation of the valve handwheel 1364 between a fully open and a fully closed position, for dispensing or containment of solid source reagent vapor, respectively.

The valve assembly thus may communicate with a discharge passage in the block that terminates at a port in which a fitting 1368 is disposed, for coupling to the discharge line 1370, as part of flow circuitry that may for example be coupled with a downstream semiconductor manfacturing tool.

For heating of the solid source reagent vessel 1302, the sidewall 1304 of such vessel may be formed with pockets 1320 and 1322 to accommodate insertion therein of respective heaters 1326 and 1330, as shown. Heater 1326 is an electrical resistance heater that is disposed in the wall opening and is connected by electrical line 1328 with a suitable electrical power supply, to effect resistance heating of the vessel wall proximate thereto. In like manner, the wall opening 1322 contains a heater 1330 joined by electrical wire 1332 to an electrical power supply, which may be the same as the power supply supplying energy to wire 1328.

In the embodiment shown, the block 134 also is heated by means of passages bored in the respective half-sections of the block, to accommodate insertion therein of heaters 1350 and 1356, which are coupled by means of electrical wires 1352 and 1358 respectively, to a suitable power supply, to effect electrical resistance heating of the block. Such heating of the block in turn heats the valve assembly 1360 and associated flow passages, whereby condensation of the source reagent vapor in such passages is prevented.

It will be appreciated that although two heaters are shown in the vessel sidewall, and two heaters are shown in the block 1340, greater or lesser numbers of heaters can be used in specific embodiments of the invention, depending on the vaporization, vapor pressure and volatility characteristics of the source reagent, and the ambient temperature conditions in which the solid source reagent delivery package is employed.

FIG. 22 is an elevation view of a solid source reagent delivery package 1380, as shrouded in a shrink-wrap film 1382, as a security and tamper-resistant feature.

One recurrent problem in the delivery of solid source reagent vapors is the difficulty of determining when the solid source reagent material is approaching exhaustion, and a new solid source reagent delivery package needs to be introduced to a process system. The invention accordingly, in additional aspects, provides embodiments in which the level of solid source reagent remaining in a vaporizer container is readily determinable.

In one embodiment, the level of source reagent material in the source vessel is monitored by pressure measurement. In such approach the solid source material is heated to increase its vapor pressure, with a heated vacuum gauge, manometer and transducer providing capability for monitoring pressure and generating an output indicative of inventory of solid source reagent in the supply vessel.

A gauge can be installed at the outlet of the vaporizer package to monitor vapor pressure at the existing process temperature, in a steady-state system. Once material is dispensed from the vaporizer vessel, the available pressure will diminish to a steady-state value, assuming that the pressure is measurable by the provided pressure monitoring components. Accordingly, for different flow rates of dispensed vapor, a different steady state value of pressure can be obtained at a specific temperature. As the vaporizer temperature is increased, the steady state value of pressure will increase. The user typically uses the vaporizer at a fixed or constant temperature level. Accordingly, the steady state pressure for a given flow rate of the source reagent vapor is readily determinable.

As material is deleted from the vaporizer vessel, the surface area of material in contact with the heated vaporizer vessel (e.g., by contact of the solid source material with a heated wall or heated support structure in the vessel) will decrease. The steady state pressure will in consequence begin to diminish, at an given flow rate and temperature, as the level of material begins to approach exhaustion. This drop in steady-state pressure can be correlated to the amount of residual material in the vaporizer vessel.

By way of example, the solid source reagent may be B₁₈H₂₂. As such material is vaporized, it is necessary to gradually increase the vaporizer vessel temperature in order to maintain a constant flow rate of the source reagent vapor. This is attributable to the vapor pressure of the source material decreasing as the material is vaporized. This may occur due to any of various causes, such as a decrease in overall surface area, or isomerization or decomposition of the solid source reagent material. It is possible to empirically determine the functional relationship between the amount of material remaining in the vaporizer vessel, the vessel temperature and the percent open character of the control valve required to maintain a predetermined flow rate or a predetermined pressure downstream of the flow control valve on the vaporizer vessel.

In another embodiment, the amount of source reagent material remaining in the vaporizer vessel is determined by charging the vaporizer vessel with a predetermined amount of heating energy over a specific amount of time. The rate at which the system reaches its equilibrium vapor pressure then can be correlated to the amount of material remaining in the vaporizer vessel. An empirical relationship thereby can be established, to relate the rate of approach to the equilibrium pressure, to the amount of material remaining in the vaporizer vessel.

The vaporizer vessel and top flange closure member may be formed of any suitable material of construction that enables the source reagent material to be heated to generate sufficient reagent vapor for dispensing to an external locus of use.

In one embodiment of a solid source reagent delivery package of the general type shown in FIG. 21, the vessel is formed of aluminum to provide high thermal conductivity for heating of the source reagent material, and the flow control valve in the valve assembly and top flange closure member also being are formed of stainless steel. In such system, the vessel may be insulated, and only the valve may be heated. Heating only of the valve ensures that the valve temperature is always higher than the temperature of the solid source reagent material in the vessel. Fabrication of the source reagent vessel from a material such as aluminum ensures good thermal uniformity of the vessel contents. The stainless steel top flange closure member provides some resistance to heat transfer and ensures that the source reagent vessel will be at a lower temperature than the valve assembly, so that solids do not condense within the valve. Heat can be inputted at the valve by a block of the type shown in FIG. 21, so that heat is conducted through the stainless steel flange closure member to the remainder of the source reagent vessel.

In another aspect, the invention addresses issues associated with very low vapor pressure (at room temperature) solid source reagents such as B₁₄ and B₁₈H₂₂, and some indium and antimony solid sources. In consequence of their very low vapor pressures, these materials must be heated to enable delivery of their vapors, but it is difficult to provide enough heating to generate the required amount of vapor.

In such instance the invention contemplates the use of a solvent in which the source reagent solid is dissolved, to provide an increased vaporization rate of the low vapor pressure solid when the solvent is volatilized. The solvent can also be used to transport low vapor pressure solid to a point of use at which the solvent and low vapor pressure solid are flash vaporized.

In utilizing a solvent to dissolve a low vapor pressure solid, any suitable solvent, including organic as well as non-organic solvents (that do not react with the solid) may be employed to increase the vaporization rate of the solid. The vapor of the solid then can be extracted from the solvent and flowed to the point of use. Alternatively, the solvent containing the dissolved solid can be flowed to a vaporizer where the solvent/source reagent mixture is flashed, with the resulting vapor then being used as desired in the further process, e.g., for cleaning of a process system chamber containing deposits that are removable by the source source reagent vapor.

In another aspect, the invention provides a technique of monitoring the solid source reagent to determine when such material is approaching exhaustion in the source reagent supply vessel. In this aspect, a heat-flux sensor is employed to determine residual solid chemistry remaining in the source reagent supply vessel. Since the chemistry is heated and vaporized during use, measurement of thermal flux can be utilized to monitor the level of source reagent remaining in the source reagent supply vessel.

Suitable heat-flux sensors are readily commercially available. In one embodiment, the heat-flux sensor is a thin-film thermopile transducer that generates a voltage proportional to the flux of heat through the sensor element, with the voltage being directly correlatable to the actual heat flux. Heat-flux sensors of such type are available from Omega Engineering, Inc. (Stamford, Conn.) as Model HFS-3 and Model HFS-4 Thin-film Heat-Flux Sensors.

By installation of the heat-flux sensor on the source reagent supply vessel, the heat flux can be monitored at all times. During steady-state operation, the heat flux will typically have a relatively small value, particularly if the supply vessel is insulated, as is desirable, and heat loss from the vessel is minimal. However, as the chemistry is depleted, the required thermal load on the supply vessel as a function of time will decrease, since there is less material to maintain at the appropriate level to generate vapor for dispensing. More importantly, heat loss will occur at the surface of the solid chemistry inside the container, so that as the solid chemistry is vaporized, heat is lost at the surface of the solid, making such area slightly cooler. Since the remaining environment will be hotter, there is an induced heat flow to the solid surface, and this flux is measured and monitored using the heat-flux sensor.

In one specific arrangement, several such heat-flux sensors are placed along the vertical axis of a supply vessel, whereby the level of chemistry in the vessel can be closely monitored over time. As the level of chemistry is depleted, the heat-flux sensor will detect the change in heat flux at the level of the chemistry. The heat-flux sensor during the majority of the dispensing operation will function at steady state, measuring heat loss due to convection from the source container to the ambient environment.

The invention in another aspect provides a solid source reagent delivery package utilizing active cooling to deliver the reagent vapor near or below room temperature. This approach can be utilized, for example, to deliver xenon diflouride to an implant source chamber. At 25° C., XeF₂ has sufficient vapor pressure to enable flow of up to several standard cubic centimeters per minute (sccm) using delivery lines of reasonable size, e.g., less than 1 inch inner diameter. However, a supply vessel filled with XeF₂ may only be able to deliver enough flow for a relatively short period of time, such as several minutes. As the material is delivered, the surface of the solid source reagent can cool due to vaporization of the material, as discussed hereinabove. To overcome this problem, an actively cooled supply vessel may be employed to maintain a temperature of 20° C.-30° C., depending on process requirements. In order to eliminate the need for heat tracing of the delivery line, the vessel can be maintained at a temperature slightly lower than the temperature of the delivery line. In this manner, the source reagent material can be delivered at sufficiently high flow rates without depositing material in the delivery lines.

Various chemistries exist that can be delivered using active cooling. In essence, this approach is applicable to any chemistry that has sufficient vapor pressure to maintain acceptable flow at temperatures between about 10° and about 50° C.

The use of a vortex cooler can be employed to rapidly cool a supply vessel at elevated temperature. For example, a supply vessel employed for delivery of octadecaborane will operate between 93° C. and 115° C. In order to remove the supply vessel after use, the supply vessel must be cool enough for an operator to handle, and a vortex cooler can be used to reduce the temperature of the vessel to a handleable condition.

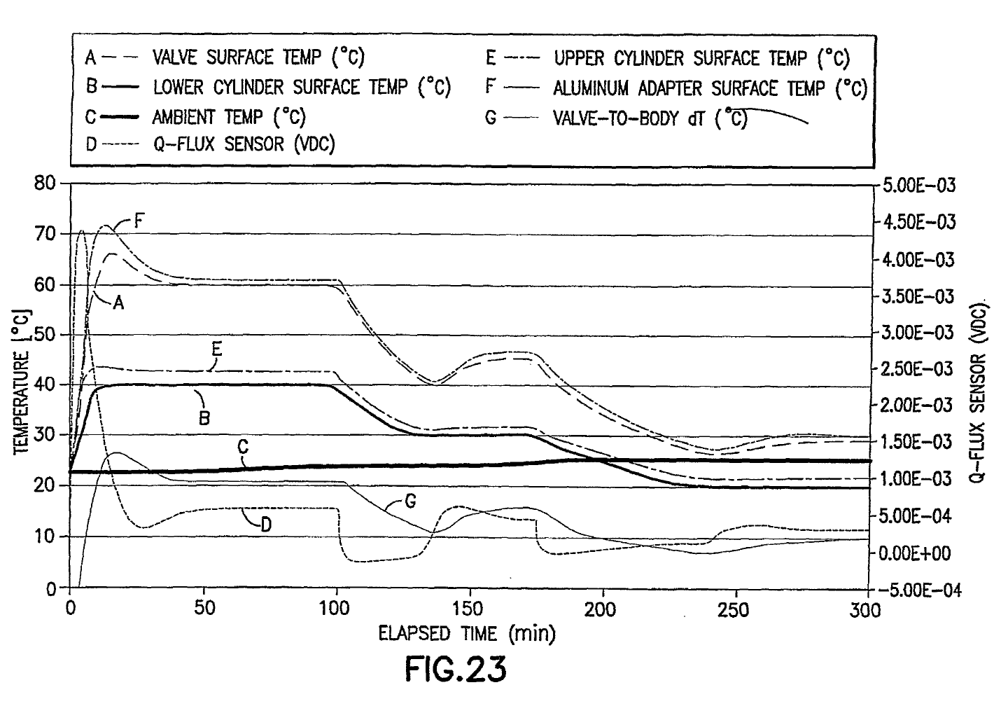

FIG. 23 is a graph of temperature, in ° C., and heat-flux sensor reading, in volts DC, as a function of elapsed time in minutes, at various locations of a source reagent supply package, including the valve surface temperature (curve A), the lower vessel surface temperature (curve B), the ambient temperature (curve C), the temperature monitored by the heat-flux sensor (curve D), the upper supply vessel surface temperature (curve E), the aluminum adapter surface temperature, of an adaptor disposed between the vessel body and the flange closure member (curve F) and the temperature difference between the supply vessel valve and the supply vessel body (curve G). The vortex cooler employed to generate the data shown in FIG. 23 was an Exair Model 3204 Vortex Cooler deployed for active cooling of the supply vessel not containing any chemistry, in a simple proof-of-concept testing arrangement.

The data shown in FIG. 23 were obtained using a supply vessel with one-loop control on the vessel body. Different wattages were applied in a parallel circuit arrangement to the valve and vessel body sections. The Exair Model 3204 Vortex Cooler was operated to remove heat form the base of the supply vessel at a constant rate. In this test, a pressure of 50 psig was applied to the cooler inlet. This pressure level corresponded to about 2 standard cubic feet (scfm) flow of nitrogen at about 0° C. (corresponding in turn to approximately 40 watts of cooling), as estimated from reference material supplied by the manufacturer of the vortex cooler device.

The invention in another aspect provides a further arrangement for monitoring the amount of solid source reagent in the supply vessel, that avoids circumstances in which the solid source reagent is exhausted in the middle of a processing run, or in which the predicted exhaustion of the supply vessel is inaccurately determined, and the supply vessel is prematurely taken out of service, and replaced by a fresh reagent supply vessel, resulting in wastage of the solid source reagent.

Simple weighing of the source vessel to determine the amount of a solid source reagent contained therein, by subtracting the tare weight of the container from the measured weight, is not a solution to this problem, since, once installed, the source vessel typically is resident in a heated enclosure in which the vessel is difficult to weigh.

The invention overcomes such issue by employing a small mid-infrared sensor that mounts directly in the vessel with the sensor head inside the enclosed volume of the vessel, in contact with the solid source reagent material. The sensor may be of any suitable type, and may for example operate in a 2 μm to 14 μm wavelength range of the infrared spectrum. Preferred sensors for such purpose include those commercially available from Wilks Enterprise, Inc. (South Norwalk, Conn.), which are in-line mid-range infrared (MIR) sensors utilizing attenuated total reflectance (ATR) sampling.

In ATR sampling, a beam of radiation is reflected internally down an infrared transmitting optical element, with the energy in the beam extending slightly beyond the surface with each reflection, so that when a sample is brought in contact with the reflecting surface, infrared energy is absorbed at wavelengths at which the sample absorbs.

More specifically, infrared radiation from a continuous source bounces on infrared absorption surfaces coated with the source material. The solid source material sits on the optical surfaces, or it is condensed as a thin film on such surfaces. Some of the light is absorbed by the thin film. As the solid source material thickness is depleted (as the solid is vaporized to generate vapor for dispensing), the infrared signal increases. An end point is reached when no more material is left, and such end point is readily determinable from a time-dependent curve. At the end point, a signal can be sent to the user, as an indication that it is time to change out the vaporizer vessel, and introduce a fresh vessel containing a full charge of the solid source reagent material.

In another implementation utilizing a mid-range infrared sensor, an IR filter is used to limit detection to an IR region in which the source reagent material absorbs.

In a further embodiment, more than one band in the infrared region is monitored, to separately monitor the solid material, and the unwanted decomposition byproducts, to alert the user to compositional changes.

In still another embodiment, the material on the infrared absorption surfaces is encapsulated in a mesh to prevent it from disengaging from the absorption surface during transportation and/or installation of the reagent supply vessel, involving physical vibration or mechanical shock being imposed on the vessel.

In still another embodiment, a mid-range infrared sensor is used to measure the amount of material dissolved in an ionic liquid storage medium, where the source reagent is in a dissolved state in such medium, with the source reagent being disengaged from the ionic liquid storage medium under dispensing conditions, and flowed out of the source reagent supply vessel.

The invention in another embodiment provides delivery of a xenon difluoride chemistry to an ion implant system, using a solid XeF₂ source material. This embodiment of the invention relates to ion implanters that become contaminated in operation, and require cleaning to maintain efficient performance. A specific issue with solid XeF₂ source material is delivering sufficient chemistry to achieve cleaning, while meeting specifications for vessels that go into the gas box of an ion implanter system, including the requirement that such vessels be capable of withstanding accidental overpressures of 1500 pounds per square inch (psi) or more.

The invention resolves such issues, in the provision of a source reagent vessel that is fabricated of aluminum, with aluminum foam insert(s) therein as a carrier structure for the solid source material, in which the metal foam insert(s) preferably are provided in a press-fit form. The aluminum foam creates a high surface area support structure that is capable of transporting thermal energy into the inner regions of the interior volume of the vessel to achieve highly efficient heat transfer and subsequent sublimation of the solid source material.

In lieu of aluminum, the source reagent supply vessel, and foam insert(s), can be fabricated of materials other than aluminum, e.g., metals with suitable conductivity and heat capacity characteristics, such as stainless steel, nickel, bronze, etc. In lieu of foam insert(s), a high surface area conductive support structure can be provided in the interior volume of the source region vessel, by a packing therein of metal wool, metal spheres, sequential trays (e.g., in a stacked array) or other packing articles or media. The packing desirably has high surface area, high void volume, good thermal properties, and good structural integrity. Spheres, when used as the packing medium, can be solid, contoured or cage-like in character, and geometric shapes other than spheres can be used, such as cubes, cylinders, etc., and in a specific embodiment, such packing medium articles can be formed of a metal foam.

As compared to vaporizers including multiple trays in the interior volume, the use of metal foams, wools, and the like, provide advantages in capacity and ease of filling. Relative to planar tray and plate structures, a three-dimensional porous network provides significantly more solid source reagent storage capacity. Further, tray and plate structures must be loaded with solid source reagent one level at a time, a process that is slow and tedious, whereas a solid source reagent material in granular or particulate form can be poured into a three-dimensional foam network, and simply shaken into position, whereby the finely divided solid is dispersed throughout the porous matrix.

In order to accommodate accidental overpressure specifications for deployment of the solid source reagent supply vessel in the gas box of an ion implanter with a high level of safety, the solid source reagent supply vessel in one embodiment is fabricated with a stainless steel conflat flange member that has been explosion bonded to aluminum. This structure provides an aluminum-to-steel transition, in an assembly allowing the strength advantages of steel to be realized at the upper portion of the structure, and the thermal conductivity advantages of aluminum to be employed elsewhere in the structure.

In another embodiment, explosion bonding is employed to create a structure with a steel upper portion, in which threading can be cut for a screw-on for a screw-in top closure member, thereby allowing the structural strength of steel to be employed at an upper portion of the solid source reagent supply vessel, and the high conductivity of aluminum to be employed in a lower portion of the solid source reagent supply vessel. Explosion bonding is a commercially available process, and may be usefully employed in fabricating solid source reagent supply vessels within the broad practice of the present invention.

In many instances, the solid source reagent vessel and porous foam insert(s) or other porous media contained therein can be subjected to surface treatments or coated to further enhance the chemical resistance of the vessel and internal structure thereof, such as may be appropriate to accommodate other, non-fluid-based chemistries. For example, the vessel and porous media may be provided with a polymer coating, or, if formed of a material such as aluminum, may be subjected to anodization or passivation treatment.

The use of solid foams as a support medium facilitates the storage and delivery of a wide variety of solid source materials. The solid source materials for such purpose may be provided in finely divided form and dispersed in the foam material by shaking, agitation, solution deposition, or other mode of incorporation, as appropriate to the specific porous medium and solid source material in a given application.

The invention therefore contemplates a solid source reagent delivery package for solid fluorine chemistries, which in a preferred embodiment is fabricated to withstand pressures of 1500 psi or higher. The vessel of such package can be of any suitable size, e.g., with a diameter of 3-8 inches and a height of 10-25 inches. In one embodiment, the vessel is 4 inches in diameter, with a height of 13 inches, and has an interior volume capacity >60 cm³. The vessel in such embodiment is formed of aluminum, with a press-fit aluminum foam insert, and with a valve and top closure flange member formed of stainless steel. The valve in such package is a manual valve with a valve conductance, Cᵥ, >2.65, which provides a maximum flowrate of 15 standard cubic centimeters per minute for a period of 1 hour.

Such solid source reagent delivery package substantially reduces the susceptibility of solid source reagents to undergo evaporative cooling and surface area agglomeration, by the provision of a porous medium in the interior volume of the vessel. Aluminum foam is a preferred insert medium material, with 5 pore per inch (ppi) foam material being highly advantageous.

The package in one embodiment includes a top flange closure member that is secured to the side wall of the vessel by bolt fasteners, as shown in FIG. 21. Alternatively, the top flange closure member can be bolted to the side wall by bolts that longitudinally pass through the entire length of the side wall, being secured at a top portion to the top flange closure member, and at a bottom portion to the floor of the vessel. In such embodiment, the floor can be fabricated as a separate member, and the top closure member and the bottom floor may each have a gasket, O-ring or other sealing element between it and the adjacent end surface of the side wall.

The top flange closure member in another embodiment can be formed as a cap that is threaded on an interior surface thereof for threadable engagement with an exterior threaded surface of the vessel, optionally with an O-ring or gasket seal being employed to form a leak-tight seal. As a further alternative, the top closure member may comprise a screw-in cap and bull plug structure, optionally with an O-ring or gasket sealing element.

The top closure member in yet another embodiment is a stainless steel flange member that is explosion bonded to an aluminum vessel.

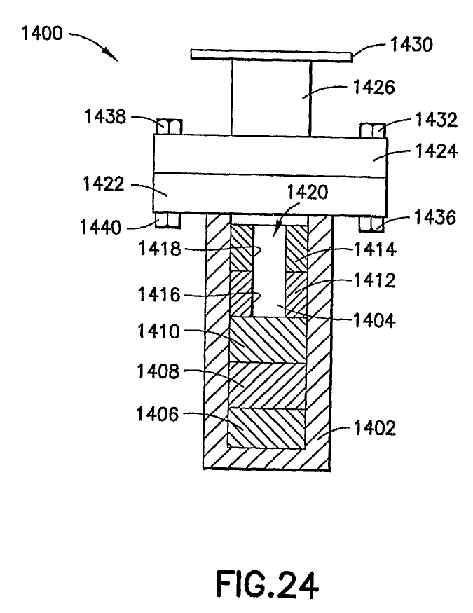

FIG. 24 is an elevation view, in partial cross-section, of a solid source reagent delivery package 1400 including a vessel 1402 defining an enclosed interior volume 1404. In the interior volume 1404 is disposed an array of vertically stacked porous metal pucks 1406, 1408, 1410, 1412 and 1414, which are press-fitted into the interior volume 1404. The upper pucks 1412 and 1414 have central bores 1416 and 1418 therein forming a passage 1420.

The vessel 1402 can be formed of a metal such as aluminum that is selected to provide thermal conductivity favorable to heat transfer into the vessel and the porous metal inserts therein, to effect generation of source reagent vapor. Explosion bonded to the vessel 1402 is a lower flange 1422 that may for example be formed of stainless steel. To this lower flange 1422 is bolted an upper flange 1424, by bolts (not shown in FIG. 24) to which are joined nuts 1432, 1436, 1438 and 1440. The upper flange 1424 has a fitting 1426 joined thereto, and a flange 1430 joined to the fitting, to accommodate coupling of a vapor dispensing line to the solid source reagent supply vessel.

The porous metal inserts in such vessel have a finely divided solid source reagent dispersed therein, in pores of the metal inserts. By incorporating the solid source reagent in the porosity of the metal foam articles, heat transmitted into the foam articles will generate vapor from the solid source reagent in a highly efficient manner.

The invention thus provides an effective solid source reagent delivery package that is particularly useful for delivery of xenon difluoride. Xenon difluoride is a white, colorless crystalline powder having a molecular weight of 169.29, and a melting point of approximately 135° C. The enthalpy change involved in the sublimation of xenon difluoride is about 13.315 kcal per mole, or, stated alternatively, about 6 cal per minute for a 10 sccm flow of XeF₂ vapor.

A preferred metal foam for use in packaging of xenon dichloride as a solid source reagent comprises aluminum foam having five pores per inch, a density of 0.189 g per cubic centimeter, a thermal conductivity of ˜4 Watts/mK, and a surface area of approximately 3.3 cm²/cm³, in the form of pucks or discs having a diameter that is approximately equal to the inner diameter of the vessel, whereby the discs can be press-fitted into the vessel, on top of one another, to form a stacked array of discs in the interior volume of the vessel.

In one preferred embodiment, a xenon dichloride solid source reagent delivery package includes a vessel having aluminum foam insert(s) therein, in which the insert(s) comprise one or more pucks, with a heating block at the upper portion of the vessel, and with active cooling at a lower portion of the vessel, to combat surface cooling and agglomeration of the solid source reagent. The active cooling capability may be provided by a vortex cooling unit associated with the lower portion of the vessel. Such package can be employed to dispense xenon difluoride vapor for cleaning of a chamber such as a microelectronic device ion implant process chamber, to remove deposits, e.g., of boron, arsenic, phosphorus, etc., resulting from ion implantation of such dopants.

The xenon difluoride dispensed from the source reagent delivery package can be subjected to plasma generation, e.g., with a carrier gas such as argon, to effect a highly efficient cleaning of ion implant process chambers after deposits of dopant species have accumulated in such chambers after a predetermined period of operation, or otherwise to such extent as to require cleaning of the chamber.

The disclosures of the following U.S. Patents are hereby incorporated herein by reference in their respective entireties, for all purposes: U.S. Pat. No. 5,518,528; U.S. Pat. No. 6,089,027; U.S. Pat. No. 6,101,816; and U.S. Pat. No. 6,343,476.

The present invention contemplates the provision of a high conductance valve useful for delivery of low pressure fluids. The valve of the present invention has a flow coefficient that is of significantly increased value, in relation to valves of prior conventional practice that have been employed for fluid delivery in low pressure applications.

Preferably, the valve of the invention is constructed and arranged to accommodate operating pressure of up to 230 psig and operating temperature in a range of from −28° C. to 150° C.

Another aspect of the invention relates to a materials delivery system including the high conductance valve of the invention attached to a material supply vessel. According to one embodiment, the material supply vessel contains materials for use in the manufacture of semiconductors, such as fluids, or alternatively solids that are heated or otherwise processed in the vessel to form fluids for dispensing. Specific examples of reagents that may be dispensed by such arrangement include, without limitation, organometallic reagents, etch reagents, cleaning reagents, photoresist precursor materials and dopants.

Another aspect of the invention relates to a system used in the manufacture of semiconductor devices, including the materials delivery system according to the invention, coupled with an apparatus for utilizing the delivered material in a semiconductor manufacturing facility, e.g., in a semiconductor manufacturing tool, for applications such as ion implantation, chemical vapor deposition, etching, cleaning, etc.

The valve of the invention is of compact character, e.g., having a valve body whose total volume (total volume here referring to the overall volume of the valve body, including the void volume of the valve chamber and the void volume of the connecting passages in the valve body) is from 4 to 20 cubic inches.

In one embodiment of the valve body, 15 to 35% of the total volume is occupied by the valve chamber (the chamber in which the valve element is movable to open or close the valve). In one preferred embodiment in which the valve body total volume is in a range of from 7 to 10 cubic inches, the valve chamber occupies a volume of from 1.5 to 3.5 cubic inches. The inlet passage in the valve body, as measured from its intersection with the valve chamber to the inlet passage opening at the surface of the valve body, can occupy from 0.15 to 0.45 cubic inch, and the outlet passage of the valve body, as measured from its intersection with the valve chamber to the outlet passage opening at the surface of the valve body, can occupy from 0.05 to 0.45 cubic inch.

In such compact valve of the invention, one preferred embodiment provides a ratio of diameter of the outlet passage to diameter of the inlet passage that is in a range of from 0.75 to 1.25, more preferably in a range of from 0.80 to 1.15, even more preferably in a range of from 0.90 to 1.10, and most preferably the ratio is in a range of from 0.95 to 1.05.

In another aspect, the ratio of lengths of the outlet passage to the inlet passage in a preferred embodiment is in a range of from 0.20 to 1.5, more preferably in a range of from 0.3 to 1.2 and most preferably in a range of from 0.35 to 1.0.

The valve of the invention thus is a small volume valve (taken herein as denoting a valve with a valve body whose total volume is <20 cubic inches), and has relatively large internal open volume in its interior. For example, the open volume of the valve (i.e., the volume determined as a sum of the individual volumes of the inlet passage, the outlet passage and the valve chamber) can be in a range of from 25 to 45% of the total volume of the valve body, and more preferably in a range of from 30 to 40% of the total volume of the valve body.

The valve of the present invention is characterized by a high conductance, and preferably has a flow coefficient greater than 2, and more preferably a flow coefficient of at least 2.5.

As a specific example, a valve of the type hereinafter described with reference to FIGS. 25-28 hereof has a flow coefficient on the order of about 2.7 to 2.9. This contrasts with valves utilized in prior practice for dispensing low pressure fluids, having flow coefficients on the order of about 0.2 to 0.35.

Considering valve operation in general, a fluid flow control valve can control fluid flow by controlling flow rate, using a change of position of a valve element in a valve housing to restrict the rate of flow of fluid through the valve body and valve chamber containing a moveable valve element. The fluid flow control valve may alternatively, or additionally, control fluid flow by imposing a specific pressure differential between fluid at the inlet of the valve and fluid pressure at the outlet of the valve, so that for a given orifice size of the valve opening, an increased pressure differential will generally effect an increased flow rate.

The flow coefficient of a valve, sometimes referred to as the capacity index of the valve, is related to the flow rate and differential pressure characteristics of the valve. Flow coefficients permit relative performance of different valves to be assessed, and permit determination of flow rate or pressure differential when one of two such variables (viz., flow rate and pressure drop) is known.

As used herein, the term valve flow coefficient, Cᵥ, refers to a flow rate expressed in gallons per minute for water at temperature of 70° F., that yields a 1 pound per square inch pressure drop across the valve. The units of the valve flow coefficient are thereby specified, and values of Cᵥ hereinafter will be referred to without dimensional units.

As used herein in reference to the valve of the invention, the term high conductance means a valve having a Cᵥ of at least 2.

The valve of the present invention achieves a substantial advance in the art, enabling low pressure fluid dispensing with high flow down to even very low fluid pressures, e.g., pressures on the order of 0.005-10 torr.

The high conductance valve of the present invention may be utilized in any of a wide variety of fluid flow applications.

In one preferred embodiment, the valve is used as a dispensing control valve for flow of a source chemistry from a vessel containing same. The source chemistry can be of any suitable form. In one specific embodiment, the source chemistry is in the form of a vaporizable solid, employed as a source of vapor for use in semiconductor manufacturing operations. In other specific embodiments, the source chemistry can be a liquid source for generation of vapor used in a downstream gas-consuming facility. In another specific embodiment, the source chemistry is a gaseous reagent that is sorptively retained on a bed of particulate physical adsorbent medium, from which the gas is desorbed under dispensing conditions for flow to an external locus of use. In still another specific embodiment, the source chemistry is a fluid that is maintained at high pressure in a vessel equipped with a fluid pressure regulator inside the vessel, in which the set point of the regulator enables low pressure dispensing of the fluid, as is for example more specifically described in U.S. Pat. No. 6,101,816.

The valve of the invention includes a valve body defining a valve chamber therein. An inlet passage communicates with the valve chamber for flow of fluid into the valve body, and an outlet passage communicates with the valve chamber for flow of fluid out of the valve body. The valve includes a valve element and actuator assembly permitting movement of the valve element between a fully open and fully closed position in the valve chamber. The inlet passage and outlet passage together with the valve chamber permit fluid flow through the valve body when the valve element is in an opened position. The inlet and outlet passages of the valve are substantially perpendicular to one another.

The respective inlet and outlet fluid flow passages in the valve body preferably are generally linear in character, and preferably are aligned at right angles with respect to one another so that the intersection of centerlines of the respective inlet and outlet passages defines an included angle of 90°.

The inlet and outlet passages in the valve body can be of any suitable shape and cross-sectional form, but preferably are of generally cylindrical shape with circular cross-section transverse to the longitudinal centerline of the passage in each instance. The respective passages may have constituent sections of differing diameter relative to one another, but any dimensional transitions along the length of the flow passage preferably are slight in character, so as to avoid any hydrodynamic effects that would significantly reduce the valve flow conductance.

The respective inlet and outlet passages each terminate at the valve chamber in the valve body. The valve chamber is appropriately sized to contain a diaphragm and stem assembly, for closure of the inlet passage, in a closed position of the valve. The valve stem extends exteriorly of the valve body and is secured to an actuating structure, such as a handle, hand wheel, automatic actuator, or other device or sub-assembly for moving the valve element in the valve chamber between respective fully opened and fully closed positions.

In one embodiment, the actuator is a handle that may be formed with a shaped or textured surface for enhanced grippability by a hand of a user engaged in manually actuating the valve.

Referring now to the drawings, FIG. 25 is a perspective view of a high conductance valve according to one embodiment of the present invention.

The high conductance valve 1510 includes a valve body 1512 having a port opening 1514 in which is disposed discharge fitting 16 defining discharge passage 1518 therein.

The valve body 1512 in the embodiment shown has a block-like conformation, with main flat side faces 1515 and minor flat edge faces 1517 defining an 8-sided block structure. The valve body may be of any suitable conformation, and may be in the shape of a rectangular parallelepiped, a cylinder, a cube, or other suitable shape.

In the FIG. 25 embodiment, the valve stem (not shown in FIG. 25) extends upwardly and exteriorly of the valve body and is engaged by a handle 1520 that may be manually grasped and rotated in a clockwise or counterclockwise fashion, to close or open the valve to flow of fluid therethrough, respectively.

The valve body 1512 may be formed of any suitable material appropriate to the fluid dispensing application. In one preferred embodiment, the valve body is a unitary machined block of 316L stainless steel material. In other specific embodiments, the valve body can be formed of aluminum, hastelloy, nickel, carbon steel, or any other suitable material of construction appropriate to the reagent being dispensed by the valve, and the temperature, pressure and other process conditions involved in the operation of the valve.

The valve is constructed of materials that provide it with operating pressure range and operating temperature range characteristics that accommodate the specific end use to which the valve is to be employed. In one embodiment of the invention, the valve has an operating pressure range of up to 230 pounds per square inch gauge (psig) and an operating temperature range of from −28° C. to 150° C.

The discharge fitting 1516 may be of any suitable type appropriate for coupling to flow circuitry or other components of the fluid dispensing system. The discharge fitting in one embodiment of the invention is a male VCR fitting. The handle 1520 may be formed of any suitable material of construction, such as a polymeric material, metal, ceramic, composite material, etc, e.g., a polyester material.

FIG. 26 is a top plan view of the high conductance valve 1510 of FIG. 25, showing the overall conformation of the handle 1520, and the male VCR fitting 1516 affixed to the valve body.

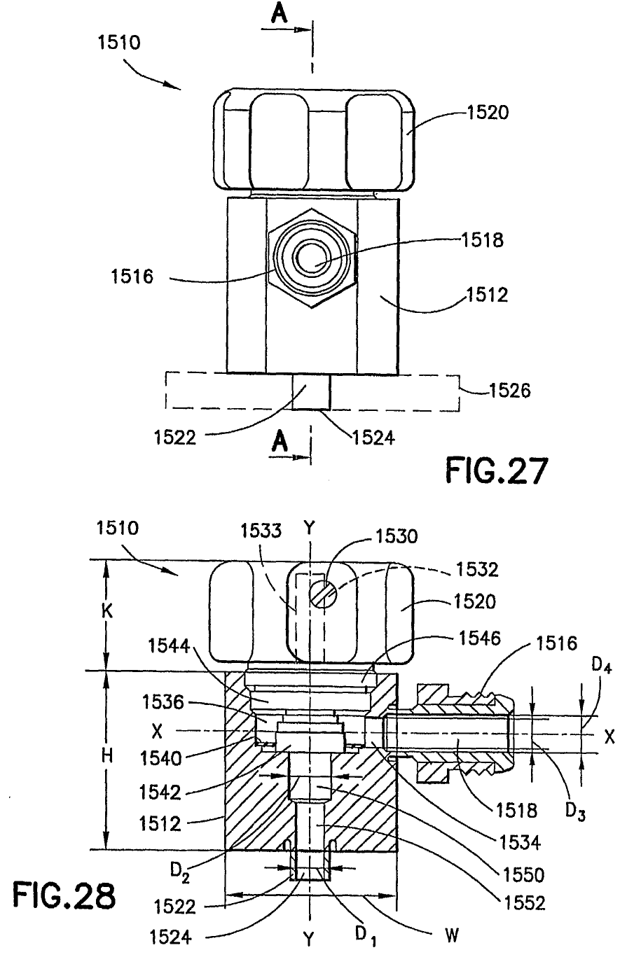

FIG. 27 is a front elevation view of the valve 1510 of FIG. 25 and FIG. 26, showing further details of the structure thereof.

The parts and features of the valve 1510 as shown in FIG. 27 are numbered correspondingly with respect to the same or corresponding structure in FIGS. 25 and 26.

As shown in FIG. 27, a tube stub 1522 is secured to the bottom face of the valve body 1512. The tube stub is coaxial with the inlet passage in the valve, as hereinafter more fully described with reference to FIG. 28. The tube stub 1522 may be secured to the valve body by welding, brazing, or other suitable joining method or technique.

In one embodiment, the tube stub 1522 is circumscribed by a flange element 1526, as shown in dotted outline form in FIG. 1527. Such flange may be employed to provide coupling structure for connection of the valve to a mating flange or other cooperating structure, to operatively position the valve for flow of fluid into the opening 1524 of tube stub 1522 during dispensing operation. The flange 26 may be welded, brazed or otherwise joined to the valve body 1512.

In another embodiment, such a flange could be machined with the valve body from a single piece of metal stock. In such unitary machined conformation, the tube stub could be eliminated and an inlet passage could be machined through the flange into the valve body.

FIG. 28 is a sectional elevation view of the valve 10 of FIGS. 25-27, taken along line A-A of FIG. 27.

As illustrated in FIG. 28, the tube stub 1522 is secured to the bottom face of valve body 1512, and defines an interior passage 1524 that communicates with inlet passage segments 1552 and 1550 in the valve body. As previously discussed, the difference in diameter between passage sections 1550 and 1552 is desirably slight and does not unduly interfere with the fluid flow. In the embodiment shown, passage segment 1550 is of slightly larger diameter than passage segment 1552, the latter being on the order of about 0.37 inch in diameter, equal to the diameter of the inlet passage in tube stub 1522. Preferably, the ratio of the diameter of the passage segment 1550 to the diameter of the passage segment 1552 is in a range of from 0.995 to 1.005.

The inlet passage formed by passage segments 1550 and 1552 is in latent communication with the valve chamber 1536. The valve chamber 1536 is formed as a cavity in the valve body 1512. The valve chamber 36 also communicates with outlet passage 1534, and the outlet passage 1534 has a diameter in a specific embodiment of about 0.37 inch, as matched to a same diameter bore in the male VCR fitting 1516. Preferably, the ratio of the diameter of outlet passage 1534 to the diameter of the bore in the male VCR fitting 1516 is in a range of from 0.995 to 1.005.

As illustrated in FIG. 28, the inlet passage formed by passage segments 1550 and 1552 has a longitudinal centerline Y-Y that is perpendicular to the longitudinal centerline X-X of the outlet passage 1534 (and associated discharge passage 1518 of the VCR fitting 1516, which is coaxial with the outlet passage 1534). In accordance with the invention, the inlet passage of the valve is perpendicular or “substantially perpendicular” to the outlet passage of the valve. The term “substantially perpendicular” means within 5 degrees of being perpendicular.

In the valve chamber 1536, the valve includes a gasket 1540 that cooperatively mates with the diaphragm/stem subassembly 1542 to close the valve to flow, in the position shown in FIG. 28. The diaphragm/stem subassembly 1542 is joined to a bonnet 1544 and an actuator bearing assembly 1546, and includes a valve stem 1533 extending upwardly from the top face of the valve body 1512 and engaged by handle 1520.

The handle 1520 is secured to the valve stem 1533 by means of a handle set screw 1530 in threaded opening 1532 of the handle. The set screw retains the handle in position for manual actuation of the valve, whereby the diaphragm/stem subassembly is translated between a fully open and fully closed position in the valve chamber 1536.

It will therefore be seen that in the position shown in FIG. 1528, the diaphragm/stem subassembly 1542 and associated gasket maintains sealing action on the inlet passage segments 1550 and 1552 and internal passage 1524 of tube stub 1522. When it is desired to dispense fluid, the handle 1520 is rotated appropriately about longitudinal axis Y-Y, to retract the diaphragm/stem subassembly from the upper end of the inlet passage, and allow flow of fluid through inlet passage segments 1552 and 1550 in the valve body, and valve chamber 1536, to outlet passage 1532. The outlet passage 1532 communicates with discharge passage 1518 of the male VCR fitting 1516, for subsequent flow of the dispensed fluid to flow circuitry, manifolding, or other locus of flow or use of the dispensed fluid.

In dispensing operation, the fluid is flowed vertically upwardly through the valve body so that it enters valve chamber 1536 and is redirected horizontally for outflow from the valve body in outlet passage 1534 communicating with discharge passage 1518.

Such “right angle-flow” of fluid through the valve body is unexpectedly superior in relation to lateral flow through fluid dispensing valves of the prior art. As indicated hereinabove, the valve of the present invention may have a valve flow coefficient, Cᵥ, that is on the order of about 2.7 to 2.9 in a specific embodiment. This is in marked contrast to performance of a corresponding prior art valve with conventional side-to-side flow through the valve body, having a flow coefficient that is an order of magnitude lower, e.g., about 0.2 to 0.3.

The valve 1510 may be of any suitable size for the end use application for which it is employed. In one embodiment, the valve body 1512 and associated handle 1520 together have a height (H+K) on the order of approximately 3.2 inches, with the valve body itself being about 2 inches in height (H). The valve body 1512 in such embodiment has a generally square conformation with respect to its main faces, with each side dimension being on the order of about 1.875 inches (W). In such illustrative valve, the fluid discharge passage 1518 of the male VCR fitting 1516 may have an inner diameter on the order of 0.37 inch, and the diameters of the tube stub 1522 (D₁) and inlet passage segment 1552 (D₁), inlet passage segment 1550 (D₂), outlet passage 1534 (D₃) and fluid discharge passage 1518 (D₄) preferably are within 10% of one another.

The high conductance valve of the present invention achieves a substantial advance in the art, with order-of-magnitude superiority over previously employed flow control valves. The valve of the present invention permits fluid dispensing to be achieved at high flow rate in low fluid pressure regimes, and is highly advantageous in application to a fluid storage and dispensing vessel from which a high extent of the gas utilization is desired.

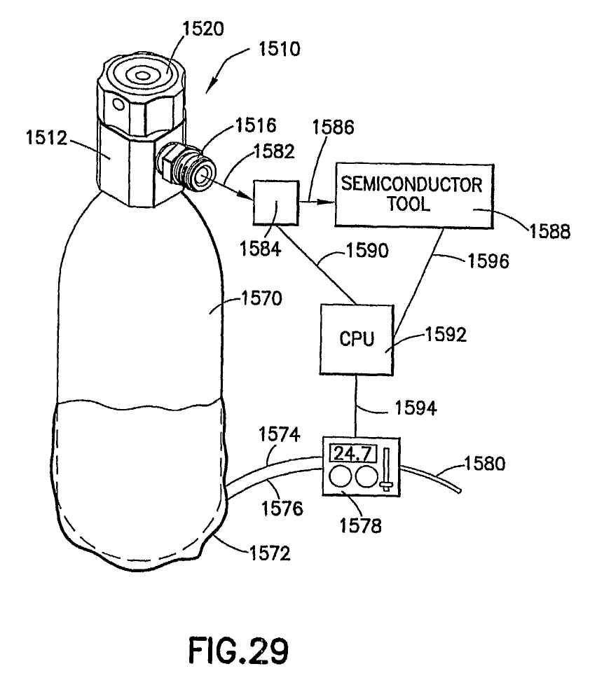

FIG. 29 is a schematic representation of a solid source reagent storage and dispensing vessel 1570 incorporating the high conductance valve 1510 of the invention, arranged in fluid flow communication with flow circuitry for delivery of fluid to a semiconductor manufacturing tool, with a heating jacket arranged for heating in response to the fluid needs of the semiconductor manufacturing tool.

As shown in FIG. 29, the high conductance valve 1510 includes valve body 1512 with which is associated the manual actuation handle 1520. The discharge fitting 16 is shown as providing an outlet for discharge of fluid. The valve 1510 is coupled to the neck of solid source reagent storage and dispensing vessel 1570, which contains a suitable solid source reagent, e.g., decaborane or octadecaborane. The lower portion of the vessel 1570 is disposed in a heating jacket 1572, which is illustratively shown as an electrical resistance-heated jacket joined by electrical wires 1574 and 1576 to the heater controller unit 1578. The heater controller unit 1578 is joined by a power cord 1580 to a suitable power source (not shown), and is selectively adjustable to transmit to heating jacket 1572 via wires 1574 and 1576 an electrical input providing a desired level of heating to volatilize the solid in vessel 1570.

The discharge fitting 1516 is illustrated as being coupled to flow circuitry shown schematically by lines 1582 and 1586 and flow control unit 1584. The flow control unit as schematically shown is representative of any appropriate flow instrumentation, sensors, motive fluid drivers, etc., such as mass flow controllers, pressure transducers, surge tanks, pumps, compressors, flow control valves, and the like, as may be necessary or desirable in the practice of dispensing the fluid reagent from the vessel 1570.

Line 1586 of the flow circuitry is connected to the semiconductor manufacturing tool 1588, which may for example include an ion implantation tool, a chemical vapor deposition tool, photoresist etching tool, or any other fluid-utilizing unit that may advantageously be supplied with fluid from the vessel 1570.

The system schematically shown in FIG. 29 includes a central processing unit (CPU) 1592, which may include a general purpose programmable computer, microprocessor, programmable logic controller, or the like. The CPU is coupled with the flow control unit 1584 via signal transmission line 1590 and with the semiconductor tool 1588 via signal transmission line 1596. The CPU thus is arranged to receive an input from the flow control unit 1584 in the flow circuitry. The flow control unit 1584 may for example include a flow monitoring device in the flow circuitry, which transmits a signal in signal transmission line 1590 to the CPU, indicative of the flow of fluid to the semiconductor tool 1588. The CPU in turn is coupled with the heater controller unit 1578 via signal transmission line 1594.

The semiconductor tool 1588 is also arranged to output a signal to the CPU 1592 via signal transmission line 1596, indicative of change in one or more parameters of the semiconductor tool that are correlative with the quantity of fluid needed by the tool.

Accordingly, if either or both of the flow control unit 1584 or semiconductor tool 1588 output a signal to the CPU 1592 in lines 1590 or 1596 that is indicative of a need for more fluid to be flowed through the flow circuitry to the tool, the CPU responsively transmits a signal in signal transmission line 1594 to the heater controller unit 1578 to cause it to increase the level of heating of the vessel 1570 by the heating jacket 1572, e.g., by increasing the electrical input to the heating jacket.

Since the valve 1510 in the FIG. 29 system is a high conductance flow valve, the dispensing of fluid from vessel 70 can be carried out in a highly efficient manner, even when the semiconductor tool is operated at low pressure conditions and requires sustained flow of fluid at significant rate.

While the invention has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

1-341. (canceled)

342. A system for processing a semiconductor device, comprising:
a materials delivery system including a reagent supply vessel containing a source material utilized in processing the semiconductor device, and an added surface area structure in an interior volume of the reagent supply vessel for supporting the source material substantially disposed within interior regions of the added surface area structure;
wherein the reagent supply vessel is adapted to deliver a process effective amount of the source material to a processing apparatus in selective fluid communication with the reagent supply vessel and operable to perform one of ion implantation, chemical vapor deposition, etching, cleaning and a combination thereof.

343. The system of claim 342, wherein said source material comprises xenon difluoride.

344. The system of claim 342, wherein said added surface area structure comprises a metal foam body.

345. The system of claim 344, wherein said metal foam body comprises a metal selected from among aluminum and aluminum alloys.

346. The system of claim 344, wherein said reagent supply vessel is of cylindrical shape, and said metal foam body comprises an aluminum foam body of cylindrical shape disposed in said interior volume of the reagent supply vessel as a press-fit insert therein, with a solid fluorine chemistry source material disposed in porosity of said metal foam body.

347. An ion implant system, comprising:
(a) an ion implanter, including a gas box adapted to hold reagent supply vessels, wherein said ion implanter in operation becomes contaminated and requires cleaning to maintain its performance; and
(b) a source of XeF₂ chemistry comprising a solid source reagent supply vessel in said gas box, said reagent supply vessel including an internal volume containing solid XeF₂ and being adapted to deliver XeF₂ vapor from said solid XeF₂ in said reagent supply vessel to the ion implanter for cleaning thereof, said reagent supply vessel containing an added surface area structure in the interior volume for supporting said solid XeF₂.

348. The ion implant system of claim 347, wherein said added surface area structure in the interior volume of said reagent supply vessel comprises at least one structure selected from among metal foam, metal wool, metal spheres, stacked tray arrays, metal cubes, metal cylinders, and metal geometric shaped articles.

349. The ion implant system of claim 347, wherein said added surface area structure in the interior volume of said reagent supply vessel comprises a metal foam.

350. The ion implant system of claim 347, wherein said added surface area structure in the interior volume of said reagent supply vessel comprises a metal foam body of elongate cylindrical form, wherein the metal foam body is in press-fit contact with the reagent supply vessel along the entire length of the metal foam body in the interior volume of the reagent supply vessel.

351. The ion implant system of claim 347, wherein said added surface area structure in the interior volume of said reagent supply vessel comprises a porous material with a three-dimensional network of porosity, and said solid XeF₂ in particulate form is dispersed within said three-dimensional network of porosity in said porous material.

352. The ion implanter system of claim 351, wherein said porous material comprises a press-fit body in contact with interior surface of the vessel in the internal volume thereof.

353. A fluorine chemistry source for cleaning of an ion implanter, said source comprising a solid source reagent supply vessel including an internal volume, and a metal foam body for holding solid fluorine source material, said metal foam body contacting interior wall surface of said internal volume, whereby the metal foam transmits heat to said solid fluorine source material for sublimation thereof.

354. The fluorine chemistry source of claim 353, wherein said metal foam body comprises an aluminum foam body.

355. The fluorine chemistry source of claim 353, therein said metal foam body comprises a stacked array of discs of metal foam material.

356. The fluorine chemistry source of claim 353, wherein said metal foam body has solid fluorine source material in particulate form in porosity throughout said metal foam body.

357. The fluorine chemistry source of claim 353, further comprising flow circuitry coupled to said reagent supply vessel for supplying vapor from said solid fluorine source material to a chamber for cleaning thereof, wherein the reagent supply vessel and flow circuitry are arranged so that said vapor dispensed from the reagent supply vessel into the flow circuitry does not condense in the flow circuitry.

358. The fluorine chemistry source according to claim 353, comprising a solid fluorine source material dispersed in porosity of said metal foam body and adapted to deliver vapor from said solid fluorine source material near or below room temperature (25° C.).

359. The fluorine chemistry source of claim 353, arranged to maintain said reagent supply vessel at temperature in a range of from 20° to 30° C., said reagent supply vessel being of cylindrical shape, and said metal foam body being of cylindrical shape and disposed in said interior volume of the reagent supply vessel as a press-fit insert therein, with a solid fluorine chemistry source material disposed in porosity of said metal foam body.

360. The fluorine chemistry source of claim 353, wherein the solid fluorine source material comprises xenon difluoride, and said vessel is adapted to generate xenon difluoride vapor solely by conduction of ambient heat through said vessel to said metal foam body, for said sublimation of said solid fluorine source material.

361. The fluorine chemistry source of claim 353, wherein said vessel comprises structural parts including a first part formed of steel and a second part formed of aluminum.

362. A method of cleaning an ion implanter, said method comprising generating XeF₂ vapor from solid XeF₂ contained in porosity of a metal foam, and contacting said XeF₂ vapor with said ion implanter for cleaning thereof.

363. The method of claim 362, wherein said metal foam comprises an aluminum foam contained in an aluminum vessel disposed in a gas box of the ion implanter, and said XeF₂ vapor is selectively dispensed from said aluminum vessel for said contacting.

364. The method of claim 362, wherein said XeF₂ vapor is generated at temperature in a range of from 20° to 30° C.

365. A method of cleaning a chamber having solid deposited material thereon that is removably reactive with xenon difluoride vapor, to remove such material, said method comprising contacting said solid deposited material with xenon difluoride vapor for sufficient time to effect removal of at least part of said solid deposited material from said chamber.

366. The method of claim 24, wherein said solid deposited material comprises at least one of boron, arsenic and phosphorus.
